(19) United States
(12) Patent Application Publication
(10) Pub. No.: US 2025/0329981 A1
(43) Pub. Date: Oct. 23, 2025

(54) SYSTEM AND METHOD FOR ICE CUTTING

(71) Applicant: Minnesota Ice Sculptures L.L.C., St. Paul, MN (US)

(72) Inventor: Robert E. Harrell, St. Paul, MN (US)

(21) Appl. No.: 19/204,244

(22) Filed: May 9, 2025

Related U.S. Application Data
(63) Continuation-in-part of application No. 18/215,728, filed on Jun. 28, 2023.
Application No. 18/215,728 is a continuation of application No. 17/727,616, filed on Apr. 22, 2022, now Pat. No. 11,692,753.
Application No. 17/727,616 is a continuation of application No. 17/243,565, filed on Apr. 28, 2021, now Pat. No. 11,898,784.
(60) Provisional application No. 63/016,783, filed on Apr. 28, 2020.
(60) Provisional application No. 63/644,928, filed on May 9, 2024.

(51) Int. Cl. H01S 3/10; G02B 6/12; H01S 5/14; H04B 10/69

(52) U.S. Cl. CPC H01S 3/10023; G02B 6/12009; H01S 5/141; H04B 10/691

(57) ABSTRACT

A system and method for making small form ice units is provided. More specifically, a novel and advantageous system and method for converting a large form ice unit into smaller form ice units is provided. Even more specifically, a novel and advantageous system and method for forming an ice sheet and for dividing an ice sheet into a plurality of elongated segments, such as ice rods, and the elongated segments into a plurality of small form ice units, such as ice cubes is provided. The system may include a formation module for forming a large form ice structure and a converting station for converting the large form ice structure to small form ice units.

### CROSS-REFERENCE TO RELATED APPLICATIONS

The present disclosure claims priority to U.S. Provisional Application No. 63/644,928 filed 9 May 2024; the present disclosure is also a continuation-in-part of U.S. patent application Ser. No. 18/215,728 filed 28 Jun. 2023, which is a continuation of U.S. patent application Ser. No. 17/727,616 filed 22 Apr. 2022, and now U.S. Pat. No. 11,692,753, which is a continuation of U.S. patent application Ser. No. 17/243,656 filed 28 Apr. 2021, and now U.S. patent application Ser. No. 11,898,784, which claims the benefit of U.S. Provisional Application No. 63/016,783 filed 28 Apr. 2020. The contents of each of these patent applications and patents are hereby incorporated by reference herein in their entirety.

### FIELD OF THE INVENTION

The present disclosure relates to a novel and advantageous system and method for making small form ice units. Particularly, the present disclosure relates to a novel and advantageous system and method for converting a large form ice unit into smaller form ice units. More particularly, the present disclosure relates to a novel and advantageous system a converting station for dividing an ice sheet into a plurality of ice rods and dividing the ice rods into a plurality of ice cubes.

### BACKGROUND OF THE INVENTION

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. There are many industries in which ice is used. The ice manufacturing industry makes ice for various uses by causing water to freeze and shaping the ice as desired. Shaping can be done while the water is freezing, by providing the water in a shaped mold, or by shaping the ice after the water is frozen, for example by cutting the ice. Different sizes of ice blocks have been formed using different sizes of molds. Approximately three hundred pound ice blocks are considered large format ice blocks.

Current systems and methods for creating clear ice are time consuming and wasteful. The process of making clear ice requires slow freezing of water with constant circulation. The water is slowly circulated to remove air bubbles from the water. If the air is not removed, then the water freezes with air bubbles, giving the ice an opaque and cloudy appearance. The freezing process can take several days for large blocks of ice.

FIG. 1 illustrates an example of a prior art clear ice block maker 10 capable of producing a large format ice block. The clear ice block maker 10 comprises a cooling unit 12, a cabinet 14, and an agitator. The cooling unit 12 includes a refrigerant and refrigeration system and can be located at the bottom of the clear ice block maker, but can also be remotely located in another location of the building 10. The cabinet 12 is a galvanized steel chamber. The cabinet 12 includes two chambers 16, each configured to hold up approximately 40 gallons of water and make an ice block with dimensions of, for example, 40″×20″×10″. The agitator is a pump that circulates the water at a constant single speed, a variable pump can be used to speed up freezing time as the ice block is in the final freezing stage. The clear ice block maker 12 requires disposable single use liners for making ice. The single-use liners facilitate holding the water in the proper shape (of the chamber) during the freezing process. This prevents the water from leaking out which causes the cooling unit to freeze up which causes the machine to freeze ice slower. The liners ensure that the ice does not freeze to the chambers. The liners also facilitate the removal of the ice from the chambers. Since small pieces of ice can be sharp, the liners can get ripped or torn or have holes punctured during the install or removal process. The liners are also used to ensure the ice blocks do not stick to the final packaging once they are boxed. The liners are also used to “help” make the ice more food safe. Because galvanized steel is not FDA approved for contact with food, the liners are also used to make the ice food safe.

To make ice, a liner is set in a chamber 16. Steps of placing a single use liner include placing the liner in the cavity, carefully aligning the liner with the sides and edges of the cavity, and fixing the liner to the cavity. To align the liner with the cavity, the bottom seams of the liner are pressed against corresponding seams in the cavity and the upwardly extending corner seams of the liner are pressed against corresponding seams in the cavity, shown in FIG. 2A. Commonly, upper edges of the liner are folded over the lip of the cavity, shown in FIG. 2B. Clips are placed over the liner and the lip, shown in FIGS. 2C and 2D.

The liner needs to be carefully placed in the chamber to minimize creases, otherwise, the resultant ice block may have small defects on 5 of the 6 sides, which typically are removed by cutting the ice. Similarly, the liner needs to be carefully pressed into the corners or the resultant ice block will not have square corners, leading to further waste. The clips are set on top of the chamber liner and are intended to be frozen into the ice.

Water is put into the liner in the cavity for freezing. If water leaks under the liner, it can reach the cold plate, causing the machine to freeze up and significantly slowing production time. More critically, when water escapes beneath the liner and comes into contact with the refrigerant lines, it can freeze around them. Because ice is an effective thermal insulator, this buildup creates an insulating barrier that reduces the system's efficiency by drastically decreasing the freeze cycle speed as ice accumulation increases. Furthermore, the ice formed around these lines can make the resulting ice blocks extremely difficult-and sometimes hazardous-to extract, especially if they become frozen solid to internal machine components. These risks highlight both a production inefficiency and a potential safety concern during the block removal process.

The water freezes the clips in place over the liner. The clips can then be used for receiving a lifting mechanism and being pulled out of the cavity. The clips then may be used to facilitate the lifting of the liner and ice out of the chamber, shown in FIG. 2e. Extraction of large ice blocks with the clips can be dangerous. More specifically, clips and hoists can break during the extraction process. In some instances, the blocks may be kept in the plastic liner for storage and handling.

There are a number of issues that arise with singe use plastic liners. The liners are very thin and can be punctured during (or before) placement in the cavity. If the liner is punctured, water leaks into the machine. If the leak is not noticed before freezing, the water will freeze in the machine and can damage the machine. Additionally, single use liners are wasteful, with a new liner being needed for each block of ice.

To freeze the water, the cooling unit 12 and agitator are turned on. Freezing of the water happens directionally. More specifically, the cooling unit 12 freezes from the bottom up. Ice is a good insulator and inhibits thermal heat transfer. As ice forms and freezing moves upwardly, the rate of freezing decreases because of the thickness of the ice. In general it can take approximately 2-3 days to freeze approximately 40 gallons of water at 10″ thickness. Current machines are configured to freeze ice blocks of at least 6-10 inches and each inch frozen that is not needed results in wasted energy, time, and product. In general, ice does not freeze level so freezing the ice block results in an uneven surface, some portion of which will be cut from the top.

FIG. 3A illustrates a prior art block hoist 20. FIG. 3B illustrates a prior art block tilt cart 30. Once the water is frozen the clips are attached to a block hoist 20. The block hoist 20 lifts the ice blocks out of the chamber and then needs to be manually pulled out and away from the machine. The block is then lowered via the hoist onto a block tilt cart 30. Ice block tilt carts 30 are used to transfer the ice and can be dangerous as the ice blocks can slide off of them while being moved. FIG. 4 illustrates a large form block of ice removed from an ice block maker.

There are a number of issues that arise with singe use plastic liners. The liners are very thin and can be punctured during (or before) placement in the cavity. If the liner is punctured, water leaks into the machine. If the leak is not noticed before freezing, the water will freeze in the machine and can damage the machine. Additionally, single use liners are wasteful, with a new liner being needed for each block of ice. Further, it is not uncommon for the plastic corners to have leaks due to manufacturing limitations. Such leaks also result in leak of water into the machine.

The formed ice block may have widely varied dimensions. For example, the block may be 20″×40″ or 40″×40″×, each with a any desired height, such as 10″. The dimensions are generally selected based on the desired form factor. A 25-pound block of ice often has dimensions of, for example, 7″×5.5″×20″. The top surface may be uneven because of the circulation of water during freezing. In some instances, for example, if the ice is frozen too quickly, a pump or pumps were to fail, and or if the pumps were not set properly (Depth) to circulate the water depending on how much ice has been frozen, the ice may have cloudy portions. The ice block can be manually trimmed to uniform thickness and to remove cloudy/opaque portions or areas having a large number of frozen air bubbles if necessary, but this can be dangerous and labor-intensive. The ice block can further be cut to the desired size and shape. For example the clear pieces may be cut into sculptures, cocktail cubes, or other ice creations. These processes are extremely labor intensive and require a vast amount of skill and expertise. The ice is manually moved from the ice block maker 10 to a platform for cutting using gloves and tools move the ice onto platforms for cutting. A great deal of care has to be taken to ensure safety and cleanliness. It is also difficult to minimize breakage or waste.

Significantly, the formed blocks of ice are generally a minimum of 10 inches thick. This is to ensure anchoring of the clips in the ice and to eliminate or reduce cracking that results from lifting the liner out of the mold. The rate of water freezing into ice decreases rapidly when the ice is more the two inches thick and continues to freezer slower and slower as each inch freezes due to the decreased thermal conductivity of the ice. There is currently no way to freeze and safely remove only 2-5″ of ice using the prior art ice makers.

Another type of large form ice is canned ice. Canned ice refers to a method of making ice via open ended rectangular forms (cans) in a chilled salt or glycol brine. This type of ice freezes from all sides and typically has an air pump to circulate the water. Ice is extracted by utilizing a warm water bath, then dumping the ice from the can.

Another issue in the ice industry relates to the standard commercially available bulk ice. When a consumer purchases a bag of ice, that ice most commonly is in the form of small tubes-or cylinders having a hollow middle. Tube ice has significant surface area, both around the outside and along the central hole. This causes the tube ice to have a relatively high melt rate.

Accordingly, large form ice (including blocks and sheets) are formed as a precursor to cocktail ice, ice sculptures, and artisan packaged ice. The ice blocks are converted to small form ice for commercial sale and use. Small form ice may include cubes, spheres, cylinders, other three dimensional geometries, and the like.

### BRIEF SUMMARY OF THE INVENTION

The following presents a simplified summary of one or more embodiments of the present disclosure in order to provide a basic understanding of such embodiments. This summary is not an extensive overview of all contemplated embodiments, and is intended to neither identify key or critical elements of all embodiments, nor delineate the scope of any or all embodiments.

The present disclosure, in one or more embodiments, relates to a system for forming small form ice units. The system may include a formation module and a converting station. The formation module may be configured to produce a large form ice structure. The converting station may be configured for cutting the large form ice structure into a plurality of elongated segments and for cutting the elongated segments into small form ice units. The converting station thus may include a first cutting station having a first cutting mechanism to cut the ice sheet into the plurality of elongated segments and a second cutting station having a second cutting mechanism configured to cut the elongated segments into small form ice units. The converting station may further comprise a redirect point between the first cutting station and the second cutting station, wherein the ice sheet travels in a first direction through the first cutting station and then is directed in a second direction at the redirect point for traveling through the second cutting station.

In some embodiments, the formation module produces ice sheets having a height of less than six inches. Such formation module may include a freeze plate, a freeze frame, and a mold, wherein the mold has a height, a length, and a width, wherein each of the length and the width are more than twice the height, and wherein the mold is supported by the freeze frame.

Each of the first cutting mechanism and the second cutting mechanism may comprise a gangsaw unit. Each gangsaw unit may comprise a plurality of mandrels and a plurality of blades on each mandrel, wherein the plurality of blades on each mandrel differ from one another either in size or spacing. In one embodiment, each gangsaw comprises three mandrels arranged in a triangular configuration and a plurality of blades on each mandrel, wherein the plurality of blades on each mandrel differ from one another either in size or spacing.

In one embodiment, the first cutting station has a first puller for moving the ice sheet to and through the first cutting mechanism and the second cutting station has a second puller for moving the plurality of elongated segments to and through the second cutting mechanism. Each of the first puller and the second puller may have a plurality of fingers having spaces therebetween, wherein the spaces accommodate blades on the first cutting mechanism and the second cutting mechanism respectively. At least one of the first puller and the second puller may be pivotable between an upper position wherein the ice sheet can be moved under the puller and a deployed position wherein the puller engages the ice sheet

In some embodiments, the formation module may include an ice block maker having a cavity and a reusable liner for use in forming the large form ice structure in the cavity. The reusable liner may have a thickness between 0.1 mm and 5 mm. The large scale ice structure may be an ice block having a height of or exceeding six inches. The system may further include a slab station, wherein the ice block is cut into a plurality of ice sheets.

The system may further include a customization module configured to engrave, stamp, or mill a surface design on the large form ice structure prior to cutting. At least one of the first cutting station or the second cutting station includes a sacrificial ice base for receiving the respective first cutting mechanism or second cutting mechanism.

The present disclosure, in one or more embodiments, relates to a method for forming small form ice units, the method comprising forming an ice sheet, transporting the ice sheet to a first cutting station, cutting the ice sheet in a first direction to form a plurality of elongated segments, and cutting the elongated segments in a second direction to form small form ice units. Forming an ice sheet may be done in a mold, wherein the mold has a height, a length, and a width, wherein each of the length and the width are more than twice the height. In some embodiments, the ice sheet has a height approximately 40 inches, a width of approximately 20 inches, and a height between 1.5 and 5 inches, and wherein the small form ice units are 2″×2″×2″ ice cubes.

The first cutting station may have a first cutting mechanism and cutting the ice sheet in a first direction may be done using the first cutting mechanism. Cutting the ice sheet in a second direction may be done by at a second cutting station having a second cutting mechanism. Alternatively, cutting the ice sheet in a second cutting direction may be done by changing an orientation of either the ice sheet or the first cutting mechanism at the first cutting station.

In one embodiment, the first cutting mechanism comprises a gangsaw unit having a plurality of mandrels and a plurality of blades on each mandrel, wherein the plurality of blades on each mandrel differ from one another either in size or spacing. The method may further comprise dynamically adjusting blade spacing or cutting speed.

While multiple embodiments are disclosed, still other embodiments of the present disclosure will become apparent to those skilled in the art from the following detailed description, which shows and describes illustrative embodiments of the invention. As will be realized, the various embodiments of the present disclosure are capable of modifications in various obvious aspects, all without departing from the spirit and scope of the present disclosure. Accordingly, the drawings and detailed description are to be regarded as illustrative in nature and not restrictive.

### BRIEF DESCRIPTION OF THE DRAWINGS

While the specification concludes with claims particularly pointing out and distinctly claiming the subject matter that is regarded as forming the various embodiments of the present disclosure, it is believed that the invention will be better understood from the following description taken in conjunction with the accompanying Figures, in which:

FIG. 1 illustrates an example of a prior art machine for making blocks of ice.

FIG. 2A illustrates an aspect of inserting a liner into a cavity of a prior art machine for making blocks of ice.

FIG. 2B illustrates an aspect of inserting a liner into a cavity of a prior art machine for making blocks of ice.

FIG. 2C illustrates an aspect of inserting a liner into a cavity of a prior art machine for making blocks of ice.

FIG. 2D illustrates an aspect of inserting a liner into a cavity of a prior art machine for making blocks of ice.

FIG. 2E illustrate an aspect of removing a formed ice block from a cavity of a prior art machine for making blocks of ice.

FIG. 3A illustrates a prior art block hoist.

FIG. 3B illustrates a prior art block tilt cart.

FIG. 4 illustrates a block of ice.

FIG. 5 illustrates a mold and a freeze frame for use with a freezing module or plate freezer to form an ice sheet, in accordance with one embodiment.

FIG. 6 illustrates a method for manufacturing ice, in accordance with one embodiment.

FIG. 7A illustrates a converting station, in accordance with one embodiment.

FIG. 7B illustrates a converting station, in accordance with one embodiment.

FIG. 7C illustrates a converting station, in accordance with one embodiment.

FIG. 7D illustrates a converting station, in accordance with one embodiment.

FIG. 7E illustrates a converting station, in accordance with one embodiment.

FIG. 7F illustrates a converting station, in accordance with one embodiment.

FIG. 8 illustrates a cutting station, in accordance with one embodiment.

FIG. 9A illustrates an ice cutting system, accordance with one embodiment.

FIG. 9B illustrates an ice cutting system, accordance with one embodiment.

FIG. 10A illustrates a converting station, in accordance with one embodiment.

FIG. 10B illustrates a frame of the converting station of FIG. 10a.

FIG. 11A illustrates an aspect of a conveyor system, in accordance with one embodiment.

FIG. 11B illustrates an aspect of a conveyor system, in accordance with one embodiment.

FIG. 11C illustrates an aspect of a conveyor system, in accordance with one embodiment.

FIG. 12A illustrates an aspect of a pull system, in accordance with one embodiment.

FIG. 12B illustrates an aspect of the pull system, in accordance with one embodiment.

FIG. 12C illustrates an aspect of the pull system, in accordance with one embodiment.

FIG. 12D illustrates an aspect of the pull system, in accordance with one embodiment.

FIG. 13A illustrates a tilting/scrap ice table, in accordance with one embodiment.

FIG. 13B illustrates an aspect of a tilting/scrap ice table, in accordance with one embodiment.

FIG. 14A illustrates an aspect of a redirect module, in accordance with one embodiment.

FIG. 14B illustrates an aspect of a redirect module, in accordance with one embodiment.

FIG. 14C illustrates an aspect of a pull system as provided on the redirect module, in accordance with one embodiment.

FIG. 14D illustrates an aspect of the pull system as provided on the redirect module, in accordance with one embodiment.

FIG. 14E illustrates an aspect of the redirect module, in accordance with one embodiment.

FIG. 15 illustrates an exit ramp of a converting station, in accordance with one embodiment.

FIG. 16A illustrates one or more enclosures of a cutting system, in accordance with one embodiment.

FIG. 16B illustrates one or more enclosures of a cutting system, in accordance with one embodiment.

FIG. 16C illustrates a user interface of the ice cutting system, in accordance with one embodiment.

FIG. 17A illustrates a reusable liner, in accordance with one embodiment.

FIG. 17B illustrates a reusable liner, in accordance with one embodiment.

FIG. 18 illustrates an example piece of shard ice.

FIG. 19A illustrates a first perspective a crushing substation, in accordance with one embodiment.

FIG. 19B illustrates a second perspective a crushing substation, in accordance with one embodiment.

FIG. 20 illustrates an ice forming and cutting system, in accordance with one embodiment.

FIG. 21A illustrates an aspect of a freeze plate module, in accordance with one embodiment.

FIG. 21B illustrates an aspect of a freeze plate module, in accordance with one embodiment.

FIG. 22 illustrates a slit module, in accordance with one embodiment.

FIG. 23 illustrates a stamp and crack module, in accordance with one embodiment.

FIG. 24 illustrates a plane and rod module, in accordance with one embodiment.

FIG. 25A illustrates an aspect of a cube and pack module, in accordance with one embodiment.

FIG. 25B illustrates an aspect of a cube and pack module, in accordance with one embodiment.

### DETAILED DESCRIPTION

The present disclosure relates to a novel and advantageous system and method for making small form ice units. Particularly, the present disclosure relates to a novel and advantageous system and method for converting a large form ice unit into smaller form ice units. More particularly, the present disclosure relates to a novel and advantageous system for dividing an ice sheet into a plurality of elongated segments, such as ice rods, and the elongated segments into a plurality of small form ice units, such as ice cubes.

Any method for forming large form ice blocks or ice sheets for conversion into a plurality of small form ice units may be used. In one embodiment, ice sheets are formed in a freezing module. The freezing module, also referred to as a freezing unit or an ice module, may be configured to form clear ice. The freezing module may include a plate freezer and/or may be incorporated in a system for manufacturing ice.

The system is modular and scalable, allowing components to be included, excluded, or rearranged based on the size of the production facility or the specific use case. The components may be reconfigured to increase output volume, change product form factor, customization of the ice, or accommodate different material types. FIG. 5 illustrates a mold 120 and a freeze frame 122 for use with a freezing module or plate freezer to form an ice sheet. The mold 120 may have sides and bottom. The mold may be single use or reusable. The freeze frame 122 may be used to provide structural integrity to the mold as it is filled with water. The bottom of the freeze frame 122 may be open. The mold and the freeze frame may have any suitable shape and size so long as they are sufficiently complementary for the freeze frame to provide support to the mold. For example, each of the mold and the freeze frame may be square, rectangular, circular, or otherwise shaped. In general, for directly forming sheet ice, it may be useful for the mold to have a depth of no more than 6 inches. For example, the mold 120 may have a depth of between 1.5 and 7 inches, a length of approximately 30-50 inches, and a width of 10-30 inches. In one embodiment, the mold has a depth of 4 inches, a length of 40 inches, and a width of 20 inches. It is to be appreciated that these dimensions are illustrative only and any suitable dimensions may be used. The mold 120 may comprise silicone, metal, plastic, thermoplastic elastomers (TPE), or other suitable materials. The freeze frame 122 may be stainless steel, aluminum, plastic, or other suitable material.

The freezing module freezes water into clear ice sheets, blocks, slabs, or molded shapes. The sheets are a form factor that is amenable to a wide variety of clear ice uses. In general, using a mold such as shown in FIG. 5, a sheet of ice may be formed wherein the sheet of ice has a length, a width, and a height, and the height is less than half of each of the length and the width. In some embodiments, the sheet of ice may have a length of 4 inches, a width of 20 inches, and a height of 2 inches. With the mold positioned on a freeze plate, ice freezes upwardly and forms a sheet of ice. The freezing module produces clear ice significantly faster and more safely than currently available ice makers, such as traditional block systems. For example, a 2-inch thick sheet of clear ice may be formed in approximately 2 to 4 hours, depending on system setup and environmental conditions. By contrast, a standard large-format block ice maker, such as a Clinebell, may require 3 to 5 days to fully freeze a comparable volume of ice. Using the sheet-based method described herein, a production cycle can yield 10 inches of clear ice via multiple sheets having a height of approximately 2″ in 20 hours, dramatically improving throughput and reducing energy consumption per batch. Additionally, this directional freezing approach mitigates many safety and handling issues common to deep block extraction.

Using systems and methods provided herein, the ice sheets may be converted into a plurality of smaller form ice products. In some embodiments, an ice block formed using a conventional ice maker may be converted into a plurality of ice sheets and those ice sheets may be further converted into a plurality of smaller form ice products using the systems and methods described herein. The systems and methods can scale to the needs of different production environments and client needs. The final smaller form ice products may have a variety of forms. In some embodiments, the final ice products comprise square cubes, rectangular cubes, or similar shapes. In other embodiments the final ice products may comprise cylinders, spheres, shards, customized with etchings, randomly formed pieces of ice broken from a larger form of ice such as an ice sheet or ice slab. In yet other embodiments, the final ice products may be formed into customized or standard sculptures.

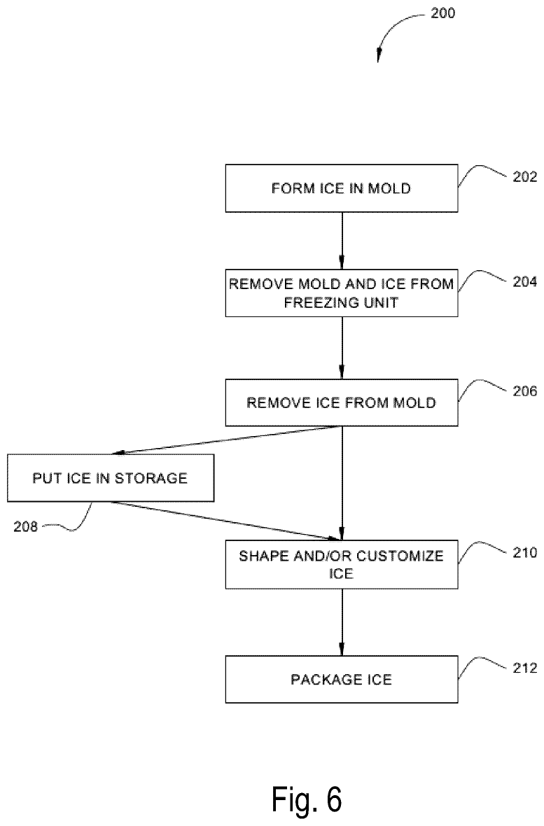

FIG. 6 illustrates a method 200 for manufacturing ice, in accordance with one embodiment. The method includes an initial step of forming ice 202. Formation of the ice may be done in any suitable manner. Forming ice may comprise, for example, forming sheets of ice, forming blocks of ice, forming slabs of ice, forming canned ice, etc.

In other embodiments, formation may be done using a freezing module such as that discussed above. In such an embodiment, ice sheets may be formed in a mold. The mold, with formed ice sheet therein, is removed from the freezing module 204 after the ice is formed. The ice sheet is demolded 206 before further processing or packaging. It is to be appreciated that, in some embodiments, the ice sheet may not be immediately removed from the mold and may be stored in the mold. If stored 208, the ice sheet may be routed to a storage area such as a holding storage freezer. The ice sheet may be shaped and/or customized 210. Shaping may comprise converting the ice sheets into predetermined sized cubes, spheres, sculptures, or other shape. Customizing the ice may comprise stamping or engraving the ice with words or symbols. After shaping, the ice is packaged 212. Each of the steps in the method, and transport of the ice between each step in the method, may be done automatically, semi-automatically, or manually. The system and method may be implemented in a variety of environments, including but not limited to ambient-temperature warehouses, refrigerated rooms, or walk-in freezers, depending on production needs, ice stability requirements, and energy management strategies.

A converting station is provided for converting an ice sheet to a desired form factor. Converting station and cutting system may be used interchangeably herein. Specific discussion is made of converting an ice sheet into smaller form ice products such as square cubes, rectangular cubes, or similar shapes. While reference is generally made to forming ice cubes, the small-form ice products may not be exactly cubic, may be a rectangular cube, or may have other shape such as a triangle.

The ice sheet may be formed using a mold such as shown in FIG. 5. Alternatively, the ice sheet may be formed by forming a large scale ice block, such as a standard 300 lb. block, and cutting the ice block into ice sheets. Cutting the block into sheets may be automated, semi-automated, or manual. The converting station may comprise a single station or a series of stations depending on the type of cube that is being cut. In general, at the converting station, the ice sheet (regardless of how formed) may be cut in one direction to form ice rods/sticks and then cut in another direction to form ice cubes or other shapes (such as triangles). In general, the ice products may have a height, width, and length and these may or may not be equal.

Any suitable type of cutting mechanism may be used for each of cutting the ice sheet into elongated segments, referred to herein as rods or sticks, and cutting the elongated segments into small form ice units, referred to herein as cubes. In some embodiments, the same type of cutting mechanism may be used to cut the ice sheet into rods/sticks and to cut the rods/sticks into squares.

In some embodiments, the converting station receives ice sheets, slabs, or blocks and processes them into smaller ice products. For example, the converting station may include a pre-processing cutting mechanism configured to trim the top surface of the ice sheet to achieve a uniform height or remove surface irregularities. A first cutting mechanism may then divide the ice sheet into a plurality of elongated rods, and a second cutting mechanism may further divide the rods into discrete cubes or other shapes.

In other embodiments, a single cutting mechanism may perform both cutting functions by reorienting either the cutting assembly or the ice sheet between passes. For example, the ice sheet may be rotated 90 degrees or the cutting head may pivot or slide to achieve perpendicular cuts. The pre-processing mechanism, first cutting mechanism, and second cutting mechanism may be of the same or different types, including band saws, gang saws, circular saws, wire saws, or other suitable cutting tools.

The converting station may optionally include a directional guide, rotation plate, or automated turning module to facilitate redirection of the ice sheet or rods between cutting stages. As described further below, the sequence of cutting operations may be manually, semi-automatically, or fully automated depending on system configuration.

In one embodiment, the top surface of the ice sheet may be trimmed using a band saw. The ice sheet may then be sliced into rods using a first circular gang saw set. The ice sheet comprising rods may be sliced into cubes using a second circular gang saw set.

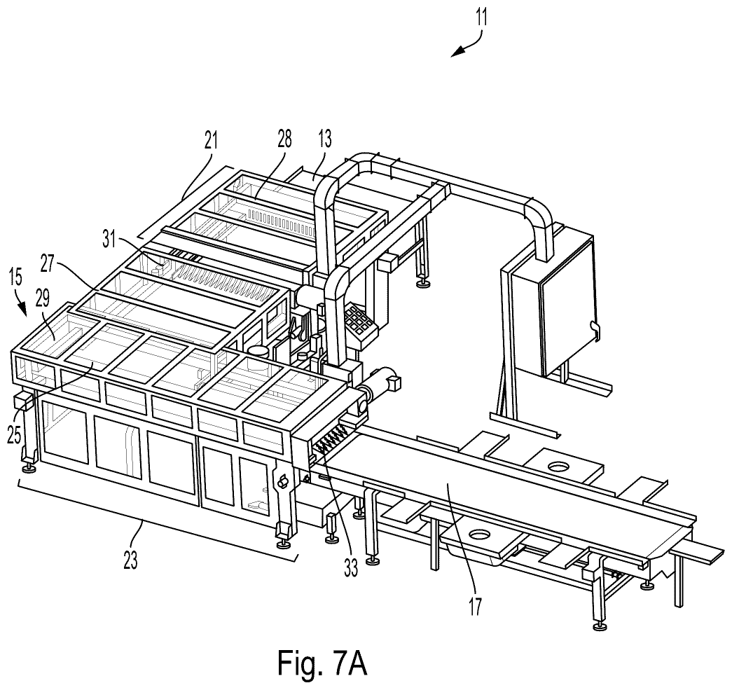

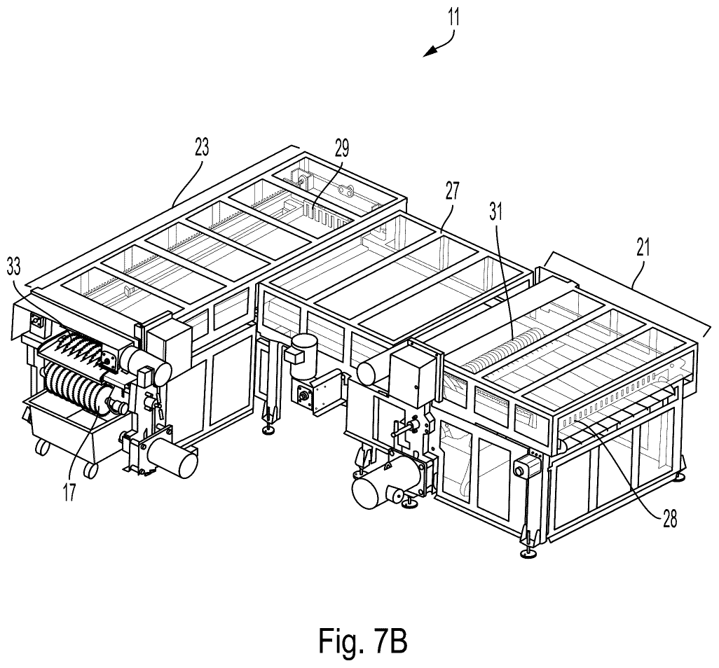

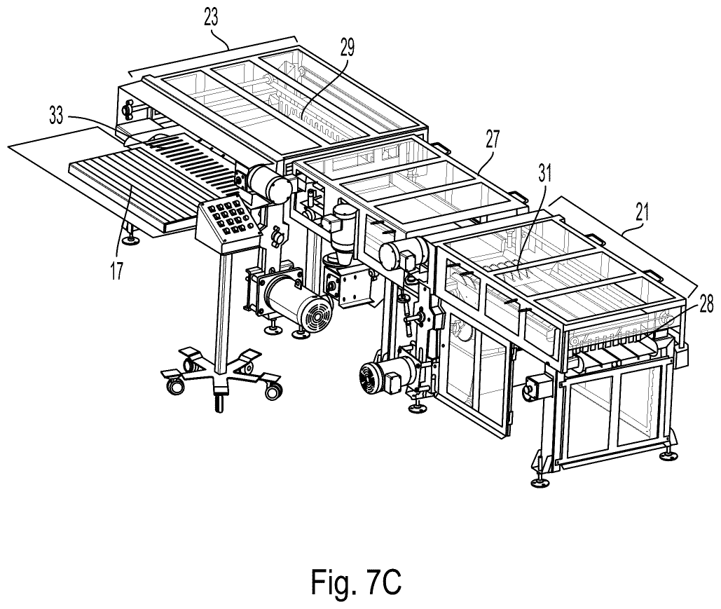

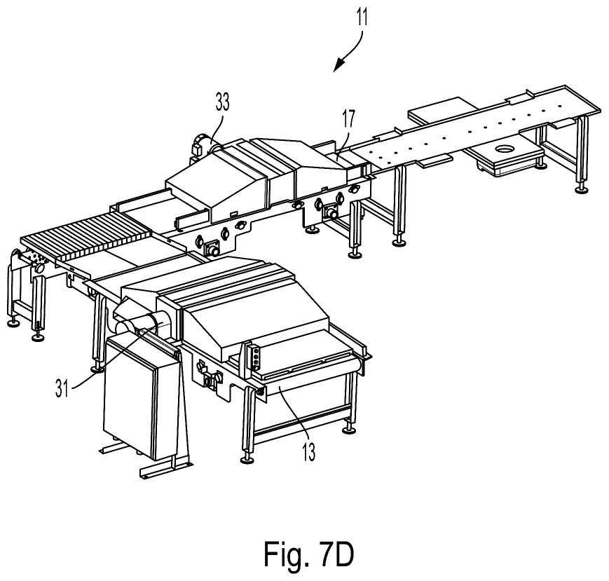

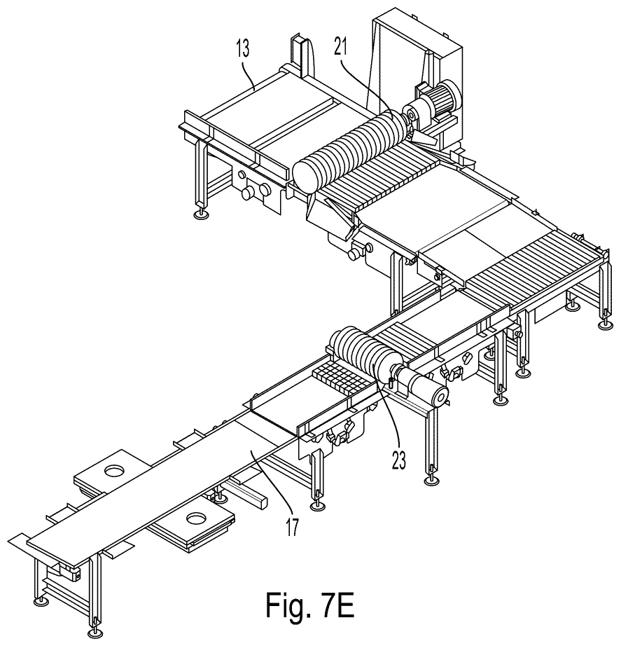

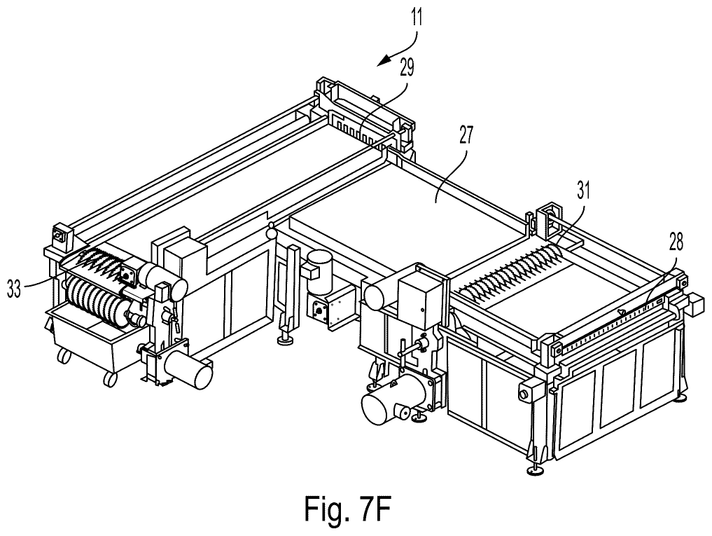

FIGS. 7A-7C, 7D, 7E, and 7F illustrate a converting station 11 in accordance with various embodiments. The converting station 11 has a loading area 13, an cutting area 15, and a removal area 17. The loading area 13 receives the ice sheet for conversion. In the embodiments shown, the cutting area 15 includes a first cutting station 21 and a second cutting station 23. The ice sheet is cut into rods at the first cutting station 21 and the rods are cut into cubes at the second cutting station 23. The cubes are moved to the removal area 17. In some embodiments, the loading area 13 and/or the removal area 17 may be specific identified areas used for that purpose. In other embodiments, the loading area 13 may simply be integral to the first cutting station 21 and/or the removal area 17 may be integral to the second cutting station 23.

FIGS. 7A-7C illustrate embodiments of a converting station 11 wherein a protective enclosure 25 encases the first cutting station 21, a conveyance area 27 between the first cutting station 21 and the second cutting station 23, and the second cutting station 23. Conveyance mechanisms 28, 29 are provided at the loading area 13 and between the conveyance area 27 and the second cutting station 23. The conveyance mechanisms 28, 29 operate to move the ice sheet between areas or stations. The conveyance mechanism 28 moves the ice sheet from the loading area and through a first cutting mechanism. The conveyance mechanism 29 moves the ice sheet from the first cutting station 21 to and through the second cutting mechanism. For ease of reference, the conveyance mechanisms 28, 29 are referred to herein as pullers 28, 29. It is to be appreciated however, that the ice sheet may be moved by pushing, pulling, or otherwise moving the ice sheet.

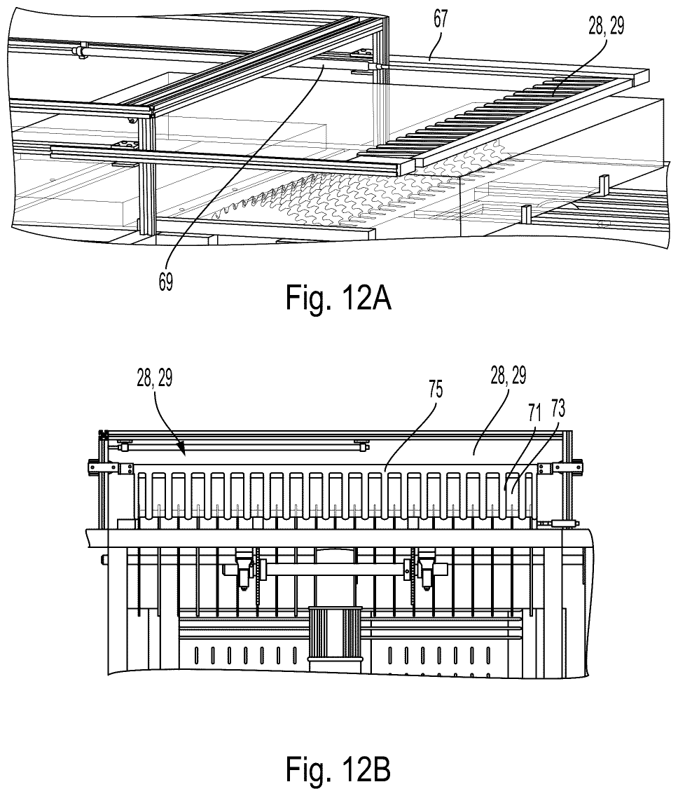

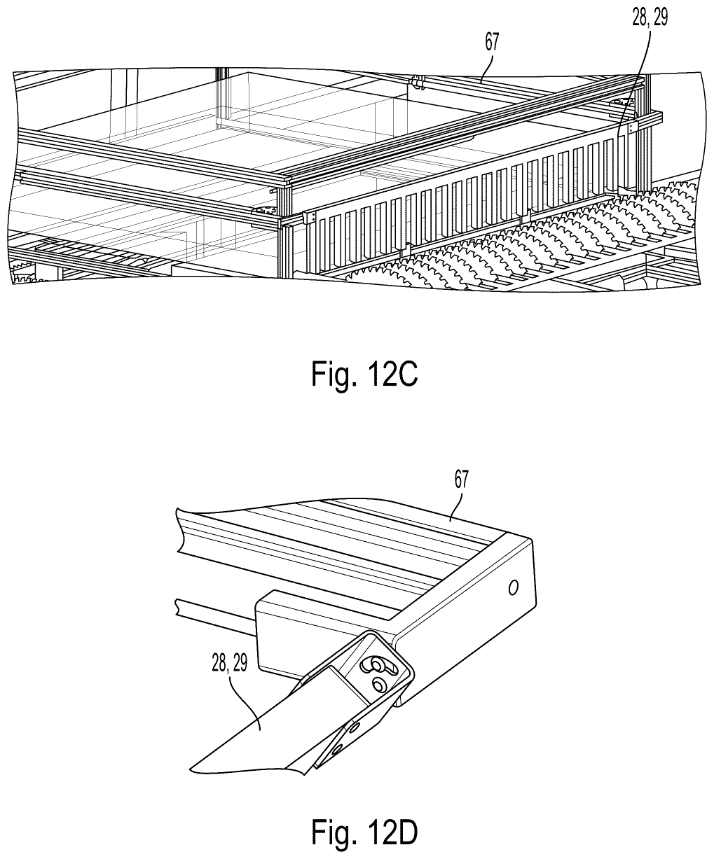

FIGS. 7A and 7B, an ice sheet is placed in the loading area 13 with the long side (40″ side) facing the first cutting station. In FIG. 7C, an ice sheet is placed in the loading area 13 with the short side (20″ side) facing the cutting area. In order to position the ice sheet for movement through the first cutting station, the first puller 28 may be manipulated, such as lifted or rotated upwardly, such that the ice sheet may be moved ahead of the puller 28. The first puller 28 moves the ice sheet in a first direction towards and through the first cutting station 21, wherein it is moved through a first cutting mechanism 31 and cut into rods. After the ice sheet is cut into rods, it reaches a second puller 29. The second puller 29 moves the ice sheet in a second direction towards and through the second cutting station 23, where it is moved through a second cutting mechanism 33 and cut into cubes. In the embodiment shown, the first direction and the second direction are perpendicular to one another. Detail about operation of pullers in accordance with some embodiments is described with respect to FIGS. 12A-12D.

After being cut into cubes, the ice sheet is moved to the removal area 17. Snow removal equipment may be provided at or near the cutting mechanisms 31, 33. Such equipment may comprise, for example, a bin for receiving snow. A pre-processing cutting mechanism, such as a trimming saw, may be provided if it is desired to trim the ice sheet but may be omitted, particularly if the sheets to be loaded into the machine are already cut flat.

FIG. 7D illustrates a converting station 11 wherein protective enclosures are provided encasing the first cutting mechanism 31 and the second cutting mechanism 33. FIG. 7E illustrates the converting station of FIG. 7D with the protective enclosures removed. In FIGS. 7D and 7E, an ice sheet is placed with the long side (40″ side) facing the first cutting mechanism 31.

The ice sheet is moved in a first direction towards and through the first cutting station 21, where it is moved through a first cutting mechanism 31 and cut into rods. After the ice sheet is cut into rods, it reaches a redirect point. At the redirect point, the ice sheet is moved in a second direction towards and through the second cutting station 23, where it is moved through a second cutting mechanism 33 and cut into cubes. In the embodiment shown, the first direction and the second direction are perpendicular to one another. After being cut into cubes, the ice sheet is moved to the removal area 17. In some embodiments, the removal area is a table or bin. In other embodiments, the removal area 17 merely refers to downstream of the second cutting mechanism 33. Snow removal equipment may be provided at or near the cutting stations. Such equipment may comprise, for example, a bin for receiving snow. A pre-processing cutting mechanism, such as a trimming saw, may be provided if it is desired to trim the ice sheet but may be omitted, particularly if the sheets to be loaded into the machine are already cut flat. Movement of the ice sheet through the converting station may be done using pullers, pushers, conveyors, manually, or by other suitable means.

FIG. 7F illustrates a stripped down version of a converting station. In FIG. 7f, an ice sheet is placed with the long side (40″ side) facing the first cutting mechanism. Now referring generally to FIGS. 7A-7F, a cutting mechanism 31, 33 is provided at each of the first cutting station 21 and the second cutting station 23. Such cutting mechanism 31, 33 may comprise a set of saws or a more than one set of saws. In some embodiments, the cutting mechanism 31, 33 comprises a plurality of saw blades provided on a gangsaw arbor. The size and spacing of the saw blades determine the sizing of the rods and cubes cut by the converting station.

An ice sheet is placed in the loading area 13, such as on a table at a first end of the converting station. The ice sheet may be placed on a plate or may be placed directly on the table. The table may be made out of stainless steel, plastic or any other suitable material. The ice sheet may be placed wide side first such that short rods are cut and then processed into cubes or long side first, such that the long rods are cut and then process into cubes. The ice sheet is moved in a first direction to and through the first cutting station 21 to cut the ice sheet into a plurality of ice rods. The subdivided ice sheet is moved in the first direction along the converting station until it reaches a redirect point. In some embodiments, the redirect point may be a corner. At the redirect point, the subdivided ice sheet is moved in a second direction to and through the second cutting station 23 to cut the ice rods into ice cubes. The ice cubes are then routed to the removal area 17. Moving of the ice sheet through converting station may be done manually, semi-automated, or automatically, or a combination thereof. Moving of the ice sheet may be done by pullers, pushers, conveyers, and/or other movement mechanism. The ice cubes may then be removed or transferred from the converting station, for example by pushing the ice cubes off of a table of the station and into a receiving container, packaging table, or packaging machine.

In some embodiments, a first puller 28 may be provided at a front of the converting station, at or near the entrance of the first cutting station 21, and second puller 29 may be provided between the first cutting station 21 and the second cutting station 23. The first puller 28 moves the ice sheet in the first direction through the first cutting station 21 for the ice sheet to be cut into a plurality of ice rods. The second puller 29 moves the subdivided ice sheet in the second direction through the second cutting station 23 to be cut into ice cubes.

In some embodiments, a conveyor may be provided at a front of the converting station, at or near the entrance of the first cutting station 21, and a puller may be provided between the first cutting station 21 and the second cutting station 23. The conveyor moves the ice sheet in the first direction through the first cutting station 21 for the ice sheet to be cut into a plurality of ice rods. The puller moves the subdivided ice sheet in the second direction through the second cutting station 23 to be cut into ice cubes.

In general, the converting station may be configured for cutting any size of ice sheet up to, for example 4 feet wide×8 feet long. For the purposes of illustration, a converting station for cutting an ice sheet that is approximately 2″×20″×40″ is described. The ice sheet may be placed on the converting station with the 20 inch side facing the first gang saw. The first puller (or other conveyance mechanism) moves the ice sheet, with the 20 inch side leading, through the first gang saw to subdivide the ice sheet into a plurality of ice rods. The second puller (or other conveyance mechanism) moves the ice sheet, with the 40 inch side leading, through the second gang saw to divide the ice rods into ice cubes. This may be done manually, semi automatically or fully automated. The ice cubes may then be transported to a further machine, such as a bagging machine or packaging table. This may be done manually, semi automatically or fully automated.

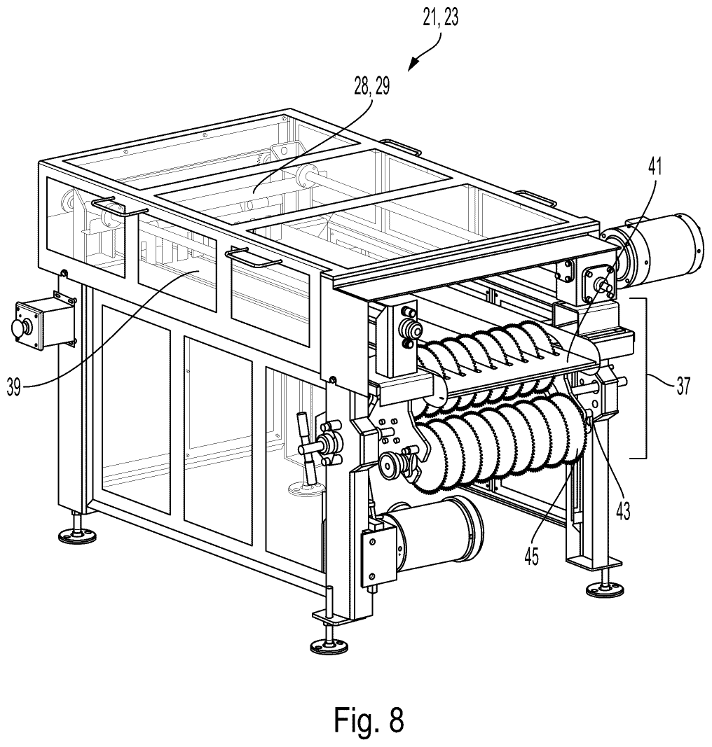

FIG. 8 illustrates a cutting station 21, 23 showing a gangsaw unit 37, a support plate 39, and a puller 28, 29. Each of the first cutting station 21 and the second cutting station 23 may include a gangsaw unit, a support plate, and a puller. In the embodiment shown, the cutting station is encased in a protective enclosure. The gangsaw unit 37 has a saw plate 41 and three mandrels 43, each mandrel holding a set of blades 45. The number, size, and spacing of blades on each mandrel may vary. In a specific embodiment, the most common ice cube sizes produced from a standard 20″×40″ ice sheet include:
1.75″×1.75″ square cubes.
2″×2″ square cubes.
2″×2″×1.75″ rectangular cubes

These dimensions are particularly suited for use in high-end cocktails and premium beverage applications. To produce these sizes, mandrels may be fitted with blades spaced at matching intervals. For example, a mandrel configured for 2″ cubes may contain 19 blades spaced 2″ apart to yield 20 rods from a 40″ length, and a subsequent 10 cuts along the 20″ side and may yield 200 total cubes.

While these cube formats are the most commercially common, the system is highly adaptable. The mandrel assembly can be easily reconfigured with custom blade counts, diameters, or spacing to accommodate alternative dimensions and geometries as required by different clients or applications. In food-grade configurations, system components may be fabricated from materials such as stainless steel, HDPE, BPA-free polymers, and other materials compliant with FDA or NSF standards. For non-food uses, alternative industrial-grade materials may be used for cost or performance optimization.

The support plate 39 supports the ice sheet through the cutting station 21, 23. The puller 28, 29 may be rotated or lifted to accommodate positioning of the ice sheet on the support plate 39. The gangsaw unit 37 may be rotated such that a desired blade size and blade sizing is used. A saw plate 41 is provided having spacing to accommodate the blades 45 on a mandrel 43. The saw plate 41 may be switched depending on the mandrel 43 and associated blades 45 being used. The puller 28, 29 similarly may have spacing to accommodate the blades 45 on the mandrel 43 such that the puller 28, 29 does not contact the blades 45 when moving the ice sheet through the blades 45 on the mandrel 43. The puller 28, 29 may be switched depending on the mandrel 43 being used and the blades 45 on the mandrel. The support plate may comprise ultra-high molecular weight (UMHD) polyethylene, stainless steel, or other suitable material. When the ice products are intended for food or beverage use, it may be desirable for the support to comprise food-safe material.

The cutting mechanisms 31, 33 may be driven using variable frequency drive motors. This enables a user to dial in on precision of the cutting depending on the hardness of the ice. Depending on hardness and environmental conditions, the chip rate of the ice may be modified. Generally speaking with softer ice, it may be desirable to cut the ice relatively quickly. In addition to being able to adjust the speed of rotation of a gangsaw, for example, a user can adjust the speed at which the ice sheet is moved through the gangsaw.

Snow may form at the cutting mechanism(s). Various snow removal elements may be incorporated into the cutting station to facilitate removal of the snow. For example, compressed air may be used to export the snow outwardly or downwardly. Heating elements may be used to melt the snow.

While gang saws and/or band saws are specifically referenced, it is to be appreciated that any cutting mechanism capable of subdividing the ice sheet into rods and dividing the rods into cubes may be used. Further, in embodiments having two cutting mechanisms, these may be the same or may be different. For example, the two cutting mechanisms may have different principles of operation. In embodiments where, for example, two saws are used, the saws may cut at different spacing to provide rectangular cubes. For example, the mandrel selected for use at the first cutting station may have spacing less than the mandrel selected for use at the second cutting station.

In an alternative embodiment, the converting station may comprise a single cutting mechanism. The ice sheet is moved in a first orientation through the cutting mechanism to cut the ice sheet into a plurality of ice rods. The ice sheet is then rotated to a second orientation, such as 90° to the first orientation and moved back through the cutting mechanism. For example, the ice sheet may be rotated by rotating a plate supporting the ice sheet. This could be in a direction opposite from the first direction such that the ice sheet is not removed from the converting station or may be in the first direction wherein the ice sheet is moved to a position in front of the saw after conversion into ice rods.

In another embodiment, the converting station may comprise a single cutting mechanism and the cutting mechanism may be rotated 90 degrees after the ice sheet is cut into a plurality of ice rods. The subdivided ice sheet is then run back through the saw, or the saw run over the ice sheet, to cut the ice rods into ice blocks.

In general, different cutting mechanisms, saws, arbors, or the like may be used to accommodate different ice sizing. For example, cutting saws may be switched out or re-spaced to accommodate different cube spacing. The system may include optional safety features such as protective enclosures, blade guards, interlocks, and emergency shut-off switches, but not limited to. These safety mechanisms may be valuable in any versions of the system, manual, semi-automated, fully automated, or high-throughput environments.

In some embodiments, the ice sheets may undergo one or more customization steps to enhance their uniqueness and functionality. This customization capability adds to the system's flexibility and adaptability in producing tailored ice products, aligning with market demands for personalized and distinctive ice creations. This may be done manually, semi automatically or fully automated.

Customization may comprise routing an ice sheet to a customization module before cutting. Such customization module may include, for example, a CNC (Computer Numerical Control) machine or a stamping machine, depending on the desired outcome. The customization step may be used to impart a design to an ice sheet. Once the design is applied, the ice sheet may be routed to a cutting state, where it may be transformed to a smaller ice product. This may be done manually, semi automatically or fully automated.

A CNC machine may be used to carve intricate designs or patterns directly onto the ice surface, allowing for complex and detailed customizations that cater to specific client requests or design specifications. This may be done manually, semi automatically or fully automated. The system supports orthogonal cutting workflows wherein the ice sheet is cut in a first direction to form rods and then redirected 90 degrees for cube formation. A turning or redirection module (e.g., conveyor corner, push-turn platform) may facilitate this transition and preserve alignment across cutting axes.

While many embodiments focus on cutting ice into cubic shapes, the system may be adapted to produce spheres, shards, cylinders, or branded blocks depending on the shape and orientation of the cutting assemblies. Optional customization modules may be included to apply branding or surface texturing prior to final cutting.

A stamping machine may be used to imprint simpler designs or logos onto the ice, offering a different approach to customization. This step in the process is crucial for creating personalized or branded ice products, enhancing their aesthetic appeal and market value. The CNC machine may imprint, for example, a design at an intended location of each ice cube or sculpture. The gantry of each of the first cutting station and the second cutting station may then be selected to cut the cubes such that the design is on each cube.

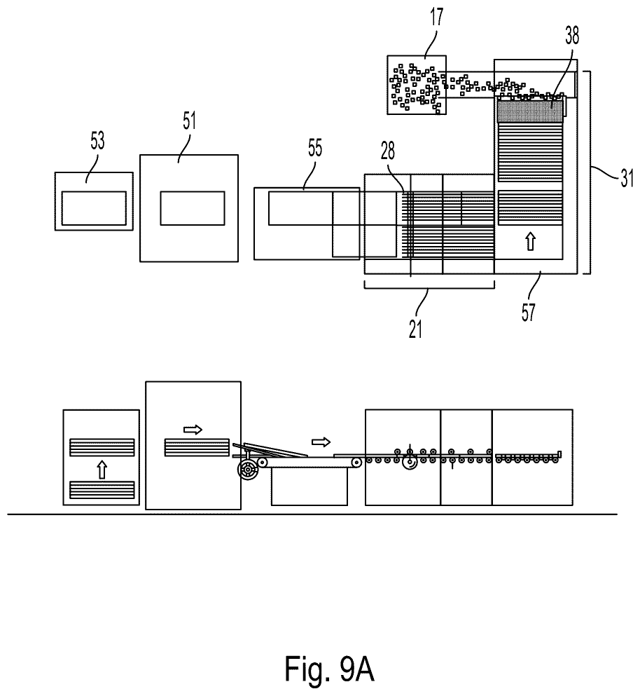

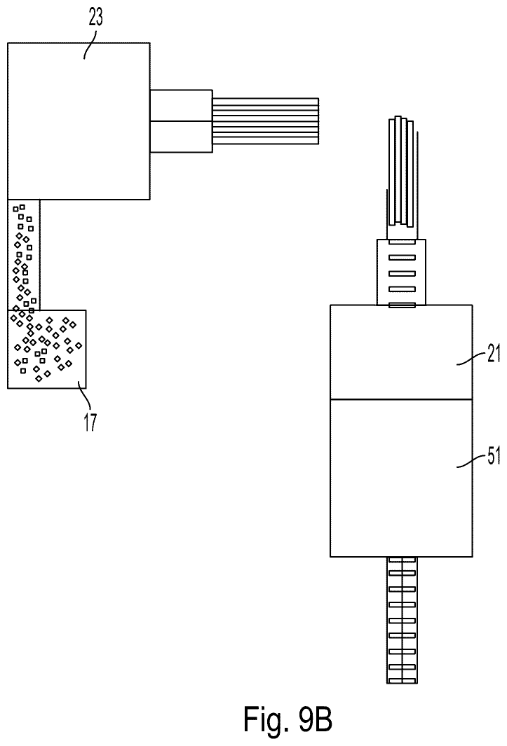

FIGS. 9A and 9B illustrate embodiments of an ice cutting system for forming small form ice units from block ice.

As shown in FIG. 9A, the ice cutting system includes a first cutting station 21 having first cutting mechanism 28 for cutting ice sheets in a first direction to form rods and a second cutting station 31 having a second cutting mechanism 38 for cutting the rods into cubes. While the ice sheets may be directly loaded into the ice cutting system, FIG. 9A illustrates forming the ice sheets from ice slabs at a slab station 51. An operator may load an ice block, for example a 300 lb. ice block, onto an elevator 53 to facilitate transfer of the ice block to the slab station 51. A transfer conveyor 55 may move the sheets to the first cutting mechanism 28. The ice sheet is directed through the first cutting mechanism 28, where it is cut into rods. After being cut into rods, the ice sheet is directed to the second cutting mechanism 38 at a redirect point 57. At the redirect point, the orientation of movement of the ice sheet is changed such that cutting the ice sheet by forward movement of the ice sheets through the second cutting mechanism 38 results in cuts in a different direction than the cuts made by the first cutting mechanism 28. In some embodiments, movement of the ice sheet is changed by 90° at the redirect point 57. The ice sheet is directed from the redirect point 57 to the second cutting mechanism 38, where it is cut into smaller form ice units. In the embodiment shown, where the redirect point changes orientation of the ice sheet by 90°, the smaller form ice units are cubic (square or rectangular). The small form ice units may then be directed to a removal area 17.

In a specific embodiment, 20″×40″ ice blocks having a height more than 2 inches are fed into the slab station. The slab station cuts the ice block into 20″×40″×2″ sheets. These may weigh approximately 60 lbs. each. The first cutting mechanism cuts the ice sheet into a plurality of 2″ wide rods. The rods are redirected at approximately 90° to be moved through the second cutting mechanism station. The second cutting mechanism cuts the rods into 2″×2″ cubes.

FIG. 9B illustrates an alternative ice cutting system wherein rods are manually removed from first cutting station 21 and fed into the second cutting station 31. In some embodiment, the rods may be moved onto a table for organization before being fed into the second cutting station 31.

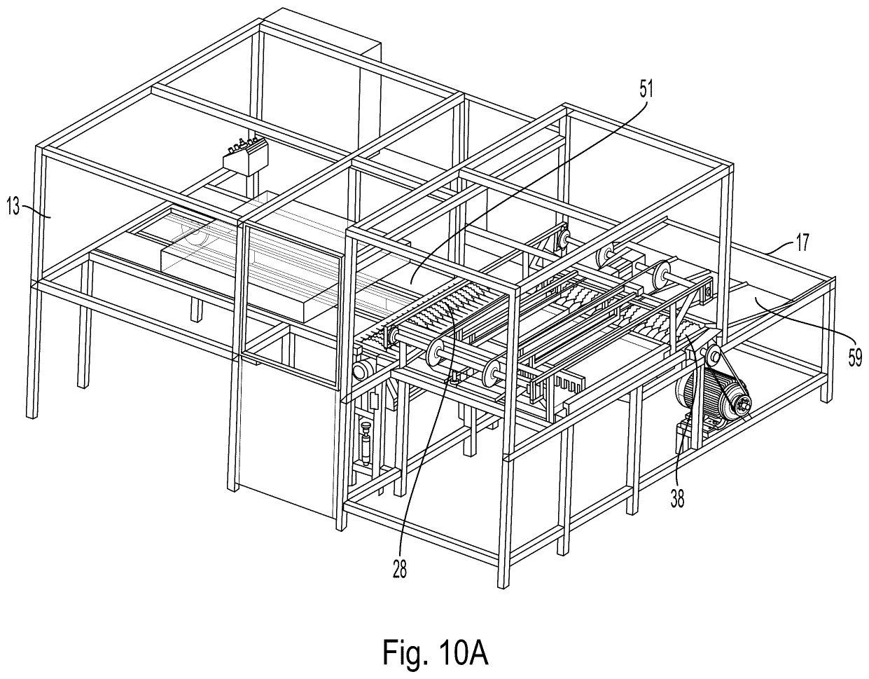

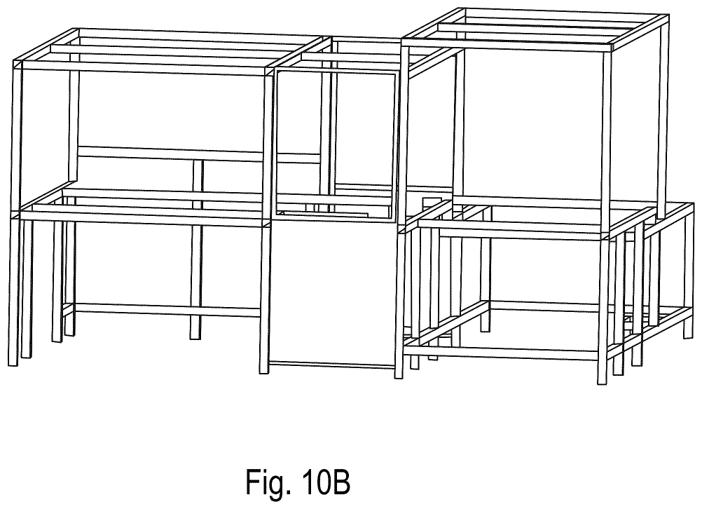

FIG. 10A illustrates the ice cutting system as a unitary converting station, in accordance with one embodiment. The converting station includes a loading area 13, an a slab station 51, a first cutting mechanism 28, a second cutting mechanism 38, an exit ramp 59, and a removal area 17. An ice block may be fed into the converting station at the slab substation 51. The slab substation 51 may include a band saw. The band saw cuts the ice block into ice sheets. The ice sheets are moved in a first direction through the first cutting mechanism. The first cutting station cuts the ice sheet into ice rods as the ice sheet is moved therethrough. The rods are moved to a redirect point and moved in a second direction 90° from the first direction through the second cutting mechanism. The second cutting mechanism cuts the rods into cubes as the rods are moved therethrough the gang saw. Each of the first cutting mechanism and the second cutting mechanism may be, for example a gang saw or a set of gang saws. As the cubes exit the second mechanism, they are directed down an exit ramp 59 to a removal area 17. Cubes may be collected from the removal area for bagging, for example. In some embodiments, a scrap ice removal mechanism may be provided at the redirect point.

In one embodiment, a gangsaw unit may be provided having a mandrel indexing mechanism configured to select between multiple blade sets arranged in a triangular configuration. The indexing mechanism may operate via manual or motorized rotation, enabling the system to quickly switch between predefined blade configurations based on desired cube dimensions. Blades used in the cutting mechanisms may be constructed from stainless steel, carbon steel, ceramic, composite, or another suitable materials. Optional surface treatments such as Teflon, food-safe coatings, or anti-corrosive plating may be applied based on material being cut or hygiene requirements in food-grade environments. Cube dimensions may vary within manufacturing tolerances of approximately ±0.125 inches. Variants in final form may be based on cutting conditions, blade wear, or ice density, and may be classified or sold by nominal size, weight, or volume.

FIG. 10B illustrates a frame of the converting station of FIG. 10A.

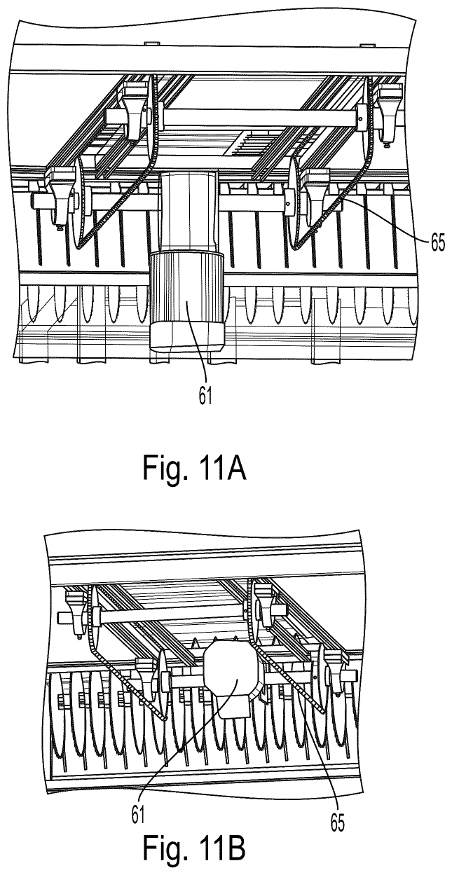

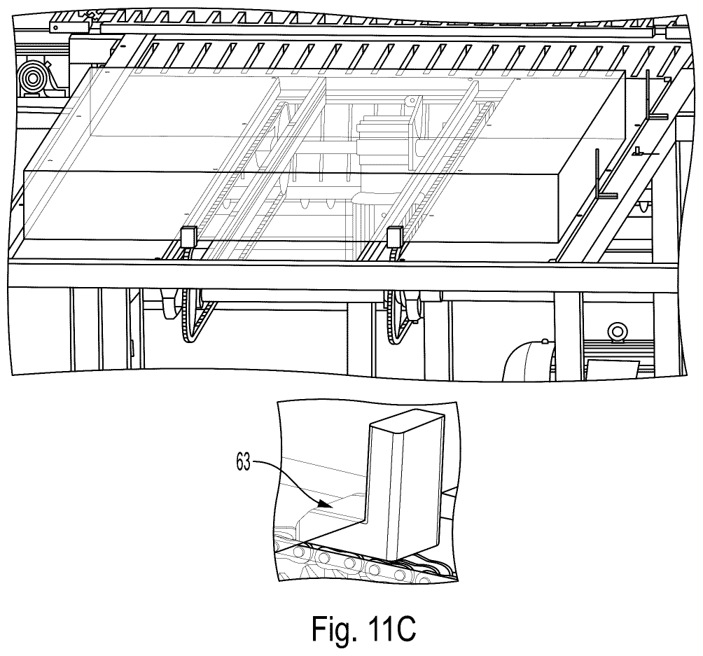

FIGS. 11A-11D illustrate aspects of a conveyor system that may be utilized in an ice cutting system, in accordance with one embodiment. The conveyor system includes two pushers 63 (see FIG. 11C) ahead of each of the first cutting station and the second cutting station, for a total of four pushers 63. The pushers may be driven by a chain drive 65, which may be powered by a motor 61. The motor may use VFD. It is to be appreciated that while an embodiment utilizing two pushers for each of two cutting stations is disclosed, other numbers of pushers may be used. In some embodiments, the pushers may push the ice, whether ice sheet or ice rods, through the cutting mechanism provided at the respective cutting station. FIG. 11D illustrates example specifications for the chain drive.

FIGS. 12A-12D illustrate aspects of a pull system that may be used with an ice cutting system, in accordance with one embodiment. The pull system works to move the ice sheet to a respective cutting mechanism. In the embodiment shown, the pull system includes a puller 28, support rails 67, and at least one pneumatic cylinder 69. The puller 28, 29 is configured for moving the ice sheet through a cutting mechanism such as a gang saw. The puller 28, 29 may comprise a rake structure having a plurality of fingers/teeth 71 having spaces 73 therebetween. A finger 71 may be provided for each ice rod. The puller 28, 29 moves the ice sheet through the gang saw with a finger 71 contacting each ice rod and the saw blades travelling through the spaces 73 between the fingers 71. The puller 28, 29 may be suspended from the support rails 67 and the pneumatic cylinder(s) 69 may operate to move the puller 28, 29.

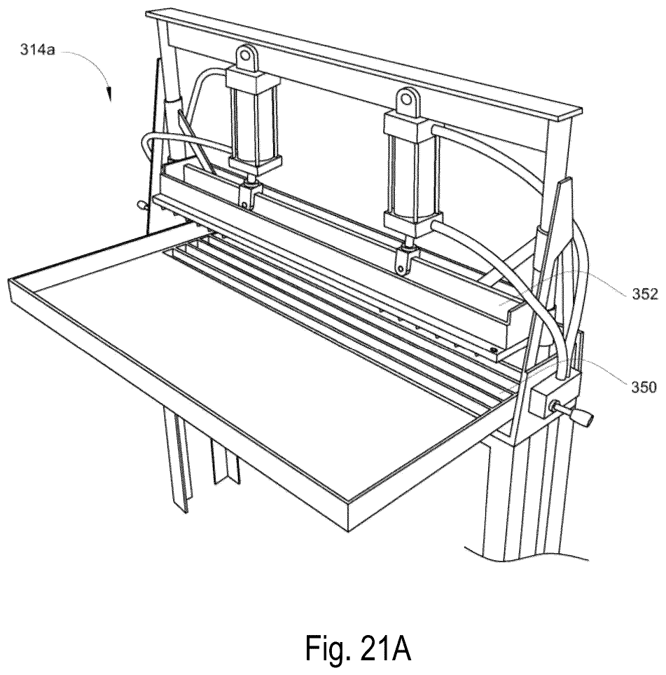

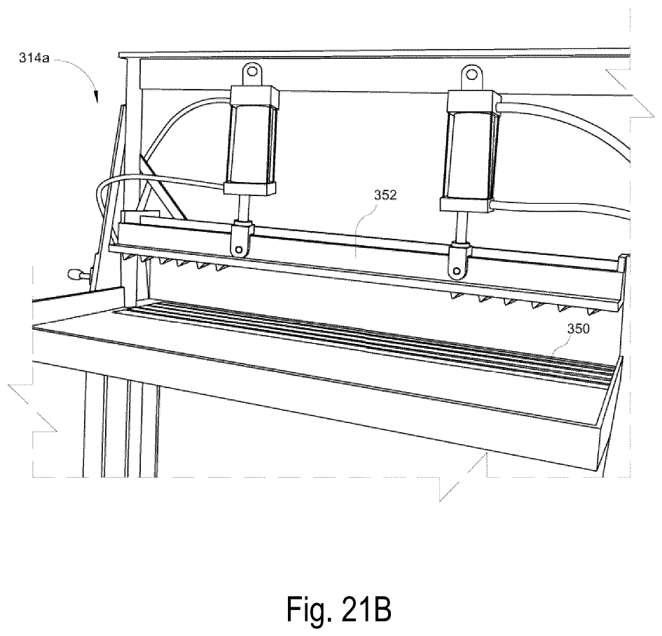

The puller may be operable to pivot from an upper position to a deployed position. In the upper position, the puller 28, 29 is pivoted upwardly such that an ice sheet can slide under the puller 28, 29. In the deployed position, The puller 28, 29 extends downwardly, at approximately 90° to the sheet of ice. In the deployed position, the fingers 71 of the puller 28, 29 engage the sheet of ice (solid sheet or rod) as the puller 28, 29 is moved to the sheet of ice. FIG. 12A illustrates the puller 28, 29 in an upper position. FIGS. 21B and 12C illustrate the puller 28, 29 in a deployed position. FIG. 12D illustrates pivoting of the puller 28, 29 relative to the rail 67. As shown, the puller 28, 29 pivots upwardly such that the ice sheet may be positioned and then pivots downwardly and drops into place to move the ice sheet. In some embodiments, a cutting system such as disclosed herein may include two pull systems, one for each of the first cutting station and the second cutting station.

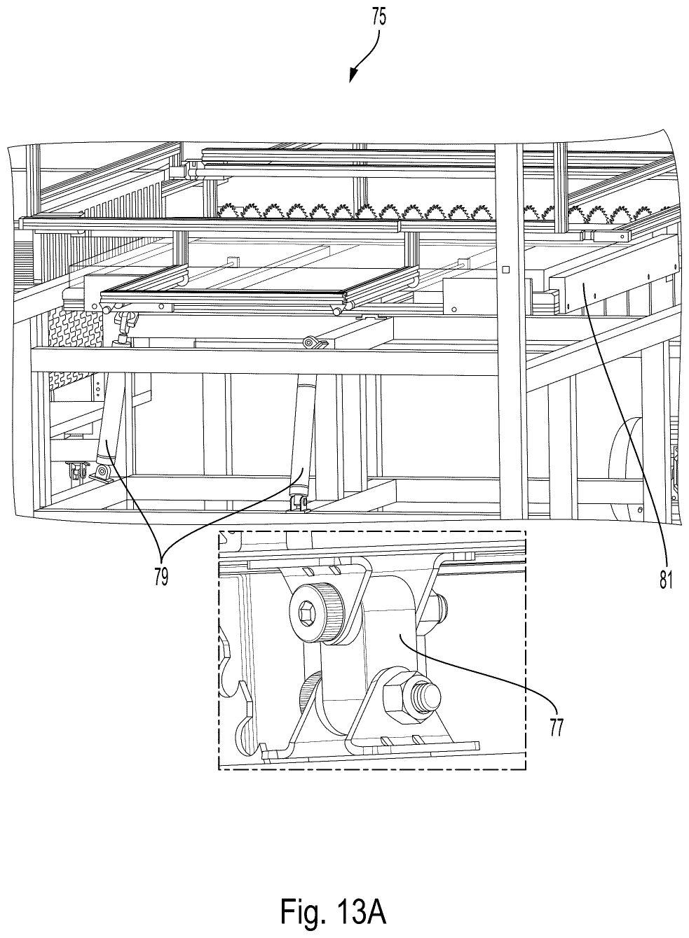

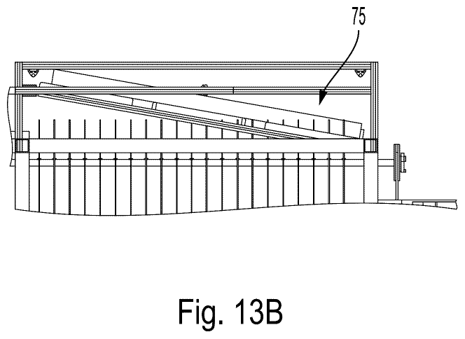

FIGS. 13A and 13B illustrate aspects of a pivoting ice table 75, in accordance with one embodiment. At various points in the cutting system, scrap ice or snow may be formed. For example, as previously described, in some embodiments, it may be useful to trim an uneven sheet or slab of ice. Trimming creates scrap ice that is removed from the sheet or slab of ice. Similarly, snow or scrap ice may be created when an ice sheet proceeds to through a cutting mechanism to be divided into rods or cubes. Accordingly, a pivoting ice table 75 may be provided as the support along various areas of the cutting system.

The pivoting ice table 75 supports the ice sheet during trimming and/or cutting. Snow or excess ice may be removed by tilting the pivoting ice table. The pivoting ice table 75 includes a top surface for supporting the ice, a two axis pivot 77 about which the table can pivot, and one or more pneumatic cylinders 79 for lifting the table to a tilted position. Retractable fences 81 may be provided to collect scrap ice and to facilitate scrap ice sliding off the table when the table is in a tilted position.

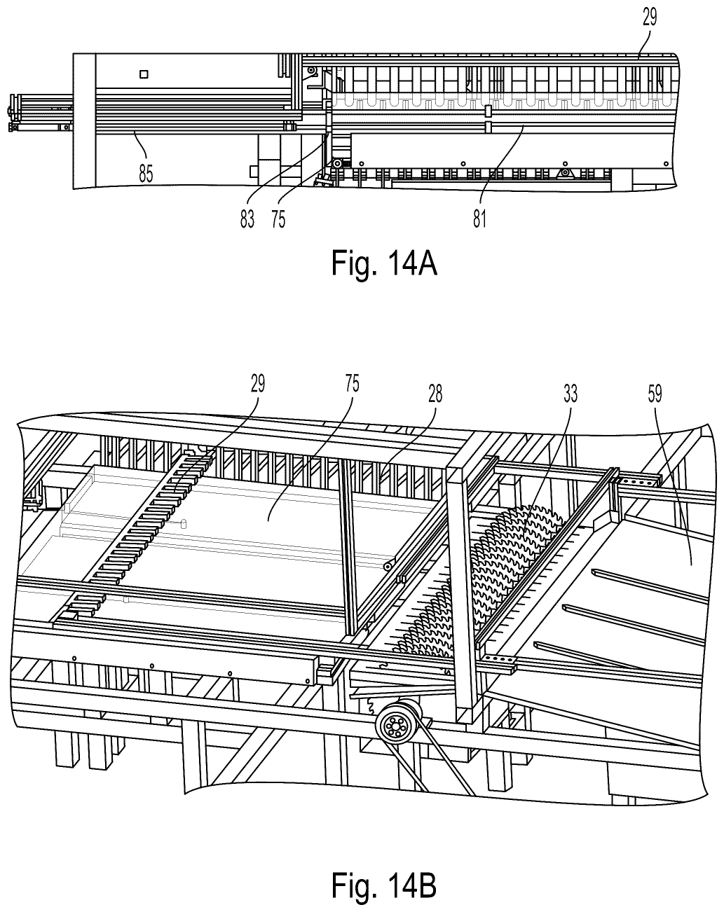

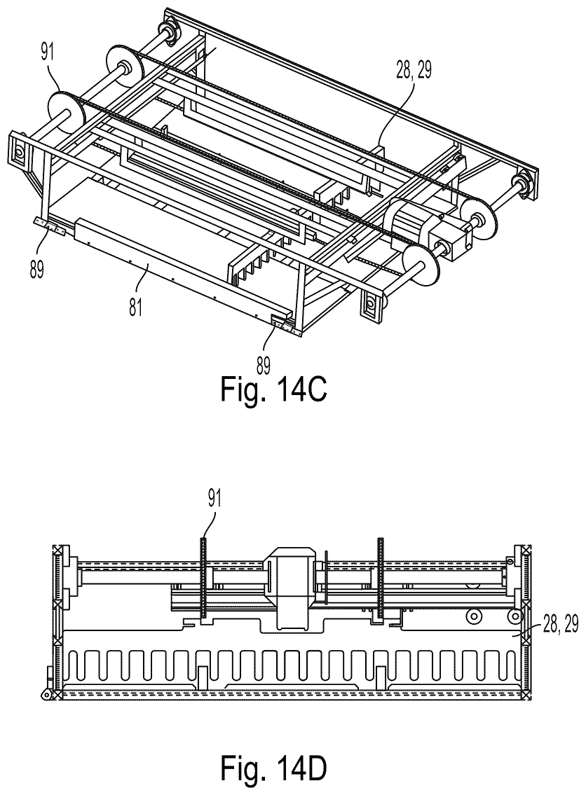

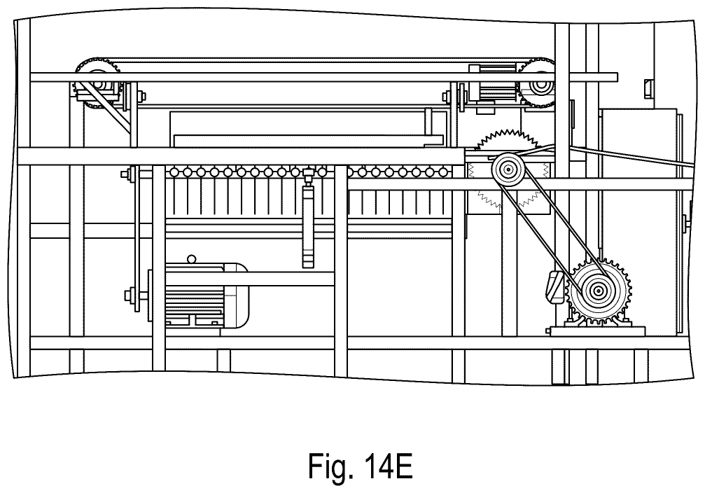

FIGS. 14A-14F illustrate aspects of a redirect point, in accordance with one embodiment. As previously described, the redirect point is a point where the ice sheet, cut into rods, has exited the first cutting station and changes orientation to be moved through the second cutting station. At the redirect point, the puller 29 before the second cutting station engages to the ice rods to redirect them to the second cutting station. In the embodiment shown, a pivoting ice table 75 is provided at the redirect point. As previously described, scrap ice may be removed from the pivoting ice table by tilting the pivoting ice table. A fence may be provided around portions of the tilting ice table. One or more cylinders may be provided to tilt the table and enable ice to slide into the fences.

The system may include a scrap removal subsystem comprising one or more of: a tilting table, grated bin, heated drain, snow collection vacuum, or scraper. These components capture and dispose of excess or broken material generated during trimming, leveling, or cutting, improving production cleanliness and efficiency. This system could be done manually, semi-automated, or fully automated depending on the requirements of the machine.

FIG. 14A illustrates the pivoting ice table 75, second puller 29, and a 3-position cylinder. The 3-position cylinder can be in a retracted position shown at 81, in line with fences on the pivoting ice table shown at 83, or extended to a redirect position shown at 85. FIG. 14B illustrates the pivoting ice table 75, the first puller 28 (in a final position where the ice sheet would have been moved through the first cutting mechanism), the second puller 29, the second cutting mechanism 33, and an exit ramp 59. The second puller 29 takes the ice sheet, for example from the 3-position cylinder, and moves it through the second cutting mechanism, and further directs the resultant cubes down the exit ramp 59.

FIG. 14C illustrates a frame supporting a fence 81, a puller 28, 29, two pivot points 89, and an overhead conveyor 91. The fence 81 holds ice product and/or scrap ice in place. The fence may be pivoted about pivot points 89. The overhead conveyor 91 may be configured to move the puller 28, 29 and may comprise one or more chain drives. FIGS. 14D and 14E illustrate aspects of the pull system.

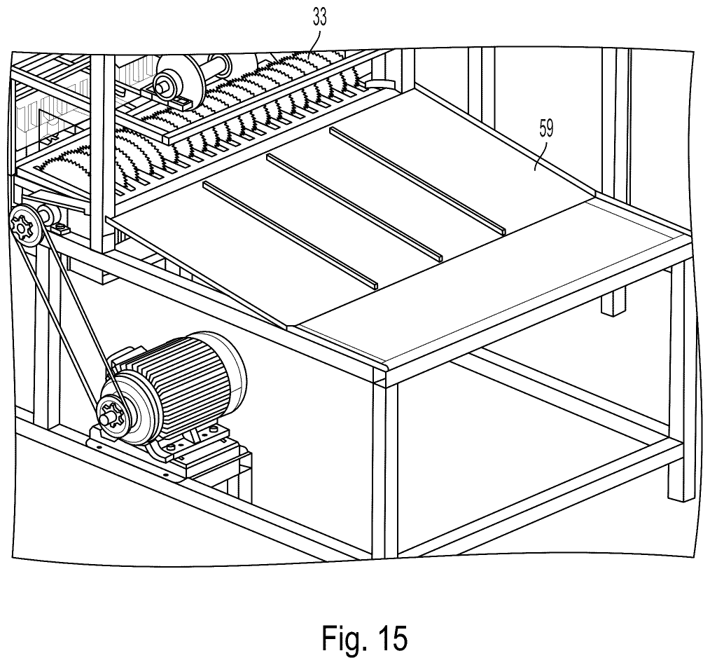

FIG. 15 illustrates an exit ramp 59 of the cutting system, in accordance with one embodiment. Ice cubes exiting the second cutting station may be directed by gravity down the exit ramp to a final point of the converting station. Cubes may be collected therefrom and bagged.

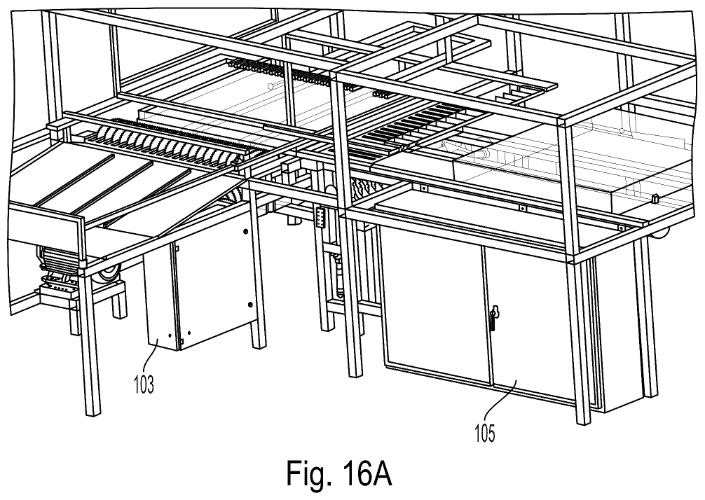

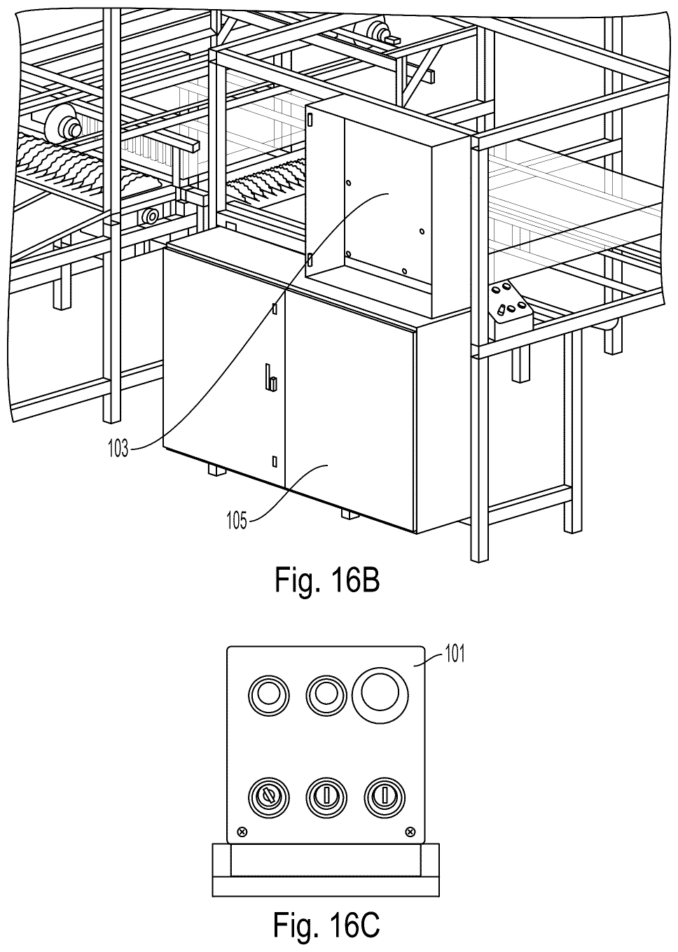

FIGS. 16A and 16B illustrate various enclosures of an ice cutting system, in accordance with one embodiment. One enclosure may be provided for housing low voltage equipment and another enclosure may be provided for housing high voltage equipment 105. FIG. 16C illustrates a user interface 101 of the ice cutting system, in accordance with one embodiment.

In various embodiments, and at various points in the cutting system, the surface (e.g. the plate) supporting the ice sheet, slab, or block, may have a base placed thereon. The base may comprise a flat slab of sacrificial ice. This prevents the surface from being marred by a cutting tool. To assist in securing the ice sheet to the sacrificial slab of ice, the machine may manually or automatically be misted or use a heating element to warm the sacrificial layer to relevel the ice and then refrozen prior to the ice slab being placed in the converting machine for processing. During use of the machine, the sacrificial ice may need to be replaced, or thawed then refrozen. In some embodiments, a metal pan having heating element may be used. The pan is filled with water, the water is allowed to freeze (for example, overnight), and the machine may cut using the ice in the pan as the sacrificial slab. A defrost cycle can be triggered, as needed, by heating the pan, causing the ice to melt. More water can be added and allowed to freeze.

During milling, snow may be created from the etched ice. There might be multiple cleaning tools may be used to clean the snow from the ice. Such cleaning tools may be, for example, a brush or compressed air or other suitable tool. Alternatively, if the slab of ice needs snow packed into the milled areas created by the milling device, the packer and scraper may be directed to pack the snow into the milled areas and scrape off any excess snow after such packing, this could be done manually or automatically. Once the snow is packed into the milled areas, it may be sanded, hand packed, or otherwise moved into milled areas. A heating element may be passed over the packed snow to create an “icy snow” to ensure that the milled area, once re-frozen, holds its appearance for as long as possible. This may be done manually, semi-automated, or automatically.

In the event it is desired to add color to the milled area of an ice piece, a cleaning tool may be used to clear out waste such as snow. A mixture of coloring material and thickening agent may be formed and inserted into the milled areas. Once the mixture has dried/frozen, snow material is inserted and packed into the milled areas. A heating element may be passed over the packed snow to create an “icy snow” to ensure that the milled area once re-frozen holds its appearance for as long as possible, all of these steps may be done manually, semi-automated, or automatically.

To fully cut ice, it may be necessary to cut all the way through the ice. As discussed, a saw plate having slots may be provided at cutting stations such that blades of a cutting mechanism may extend through slots in the cutting plate. Alternatively, a cutting surface may be provided into which the blades may cut. The cutting surface may be a base ice slab. More specifically, a sacrificial slab of ice may be positioned for receiving the ice sheet as it is cut. The cutting mechanism can press into the base ice slab. As ice is processed through the converting station, the cutting process cuts numerous pieces of ice out of the base ice slab. This can cause the base ice slab to wear down and become uneven and unstable. To prevent or reduce this, the base ice slab may be restored as needed between processing of ice. Such restoration may be manual or may be done by the converting station. For example, the converting station may include a refreeze system comprising a self-leveling pan of water, heating coils (located under the base slab of ice), a water fill pump, and a freezer (such as a plate freezer). For minor repairs, water may be misted over the sacrificial ice and the water will adhere as ice. In various embodiments, the sacrificial ice may be replaced, a troch or container full of water may be used to adhere ice to the sacrificial ice layer, freeze snow/snowing ice mix may be packed around the ice sheet to ensure placement during processing, etc.

When the base slab needs to be defrosted and refrozen to ensure a level sacrificial surface of ice, the converting station may pause until the refreezing task is completed. This process can be completed manually, semi-automatic or automatic. Refreezing comprises turning on the heating coils of sorts/hot gas defrost from the refrigeration compressor, located under the base slab ice, to turn on. These remain on for an allotted amount of time until the ice has melted. The water pump can then be used to add water to restore the base slab of ice to the correct size. The water may be added manually. A water level sensor may be provided to detect when sufficient water has been added. Otherwise if being completed manually, the operator will need to understand how full to fill it. The heating coils are turned off and the plate freezer is turned on. Turning off the heating coils and turning on the plate freezer may be directed by the controller. Freezing may continue for a suitable amount of time for the base ice slab to be frozen and ready for leveling. A milling gantry can be used to load a tool, such as an end mill, for leveling the base slab of ice. Such leveling may comprise directing the milling tool to pass back and further across the surface to level the base ice slab.

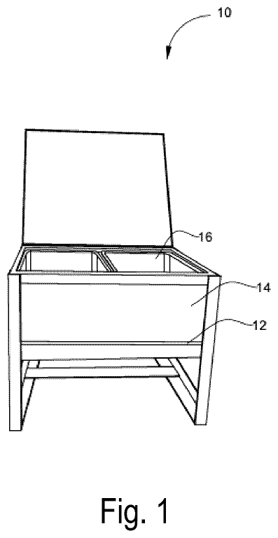

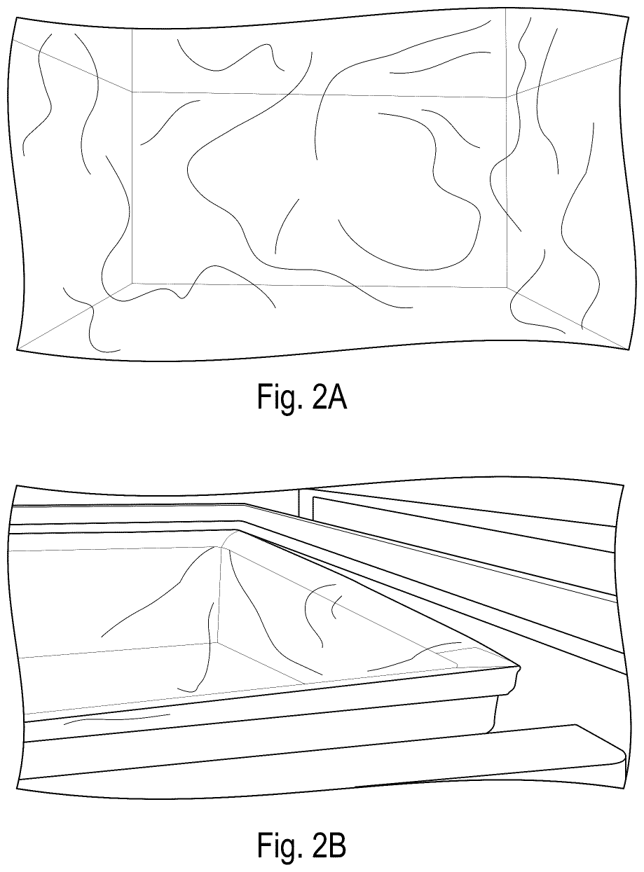

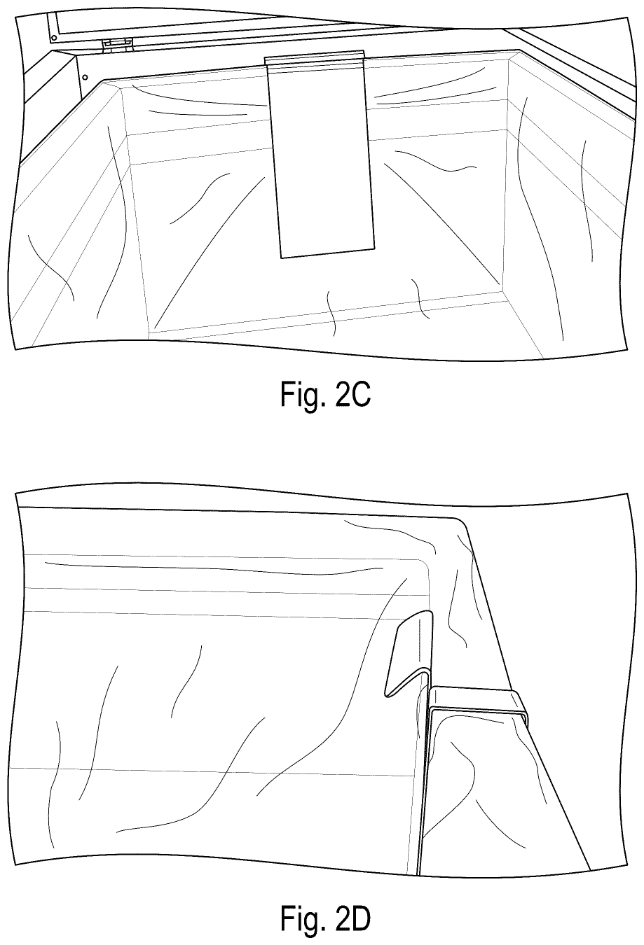

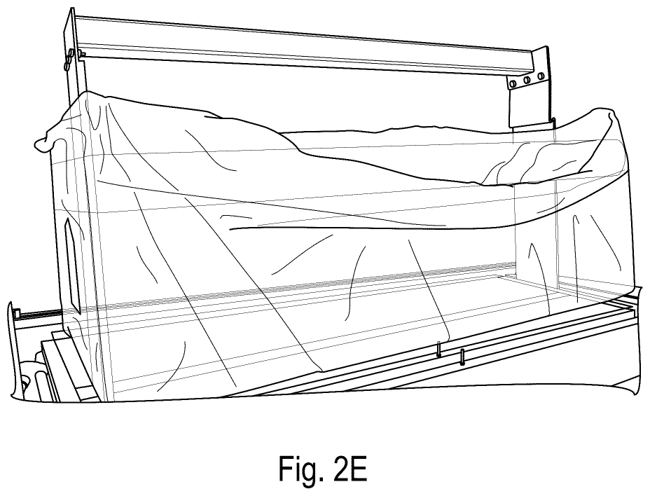

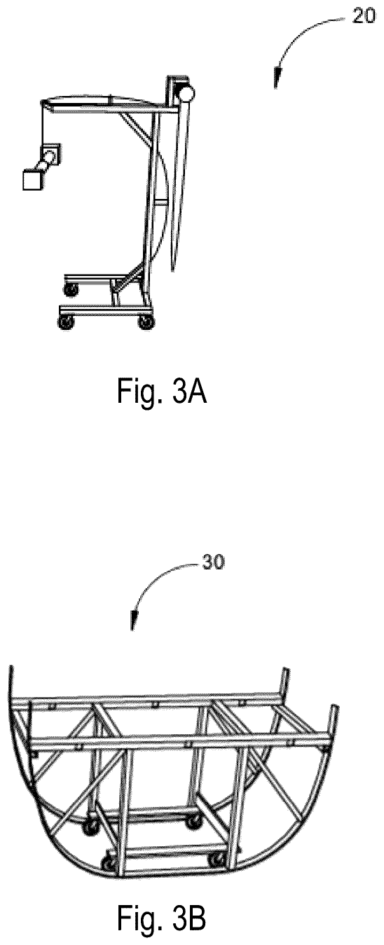

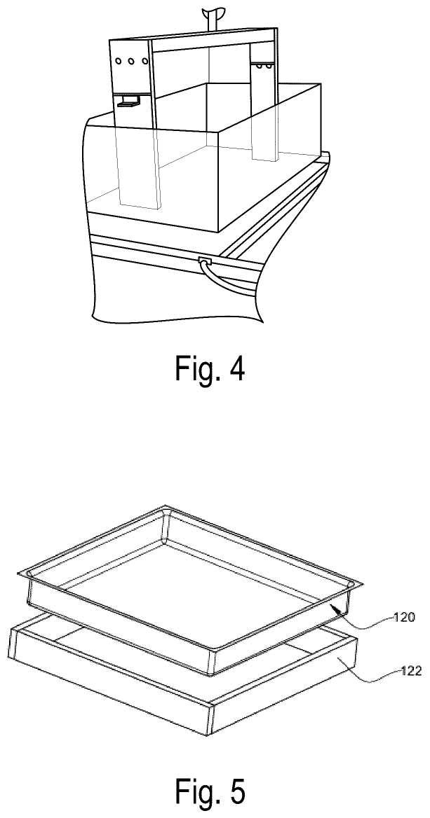

As previously discussed, in some embodiments a large form ice block may be formed and subdivided into ice sheets for further processing. Such ice block may be formed using a block ice machine. FIG. 1 illustrates a block ice machine for making two large ice blocks per cycle. Typically, to form a block of ice, single use plastic liners are placed in each cavity.

The present disclosure provides a reusable liner that may be used to form ice blocks. The liner may be sized to form any useful size ice block.

In some embodiments, the reusable liner comprises a silicone liner. In other embodiments, the reusable liner may comprise flexible food-grade materials such as thermoplastic elastomers (TPE) and other suitable polymers in addition to silicon. The liner thickness may range from approximately 0.125 mm to 4 mm, depending on the required durability, flexibility, and insulation properties. Thinner liners (e.g., 0.125 mm to 1 mm) may be suitable for smaller molds or single-use applications, while thicker liners (e.g., 2 mm to 4 mm) may be preferred for reusable liners that require greater structural integrity and puncture resistance during commercial production. In general, the material may be food-grade silicone and BPA-free. The reusable liner may comprise a single layer or a multi-layer. In a multi-layer embodiments, the outer layer(s) facing the cavity may comprise a silicone and the inner layer(s) may comprise polyethylene or other polymers.

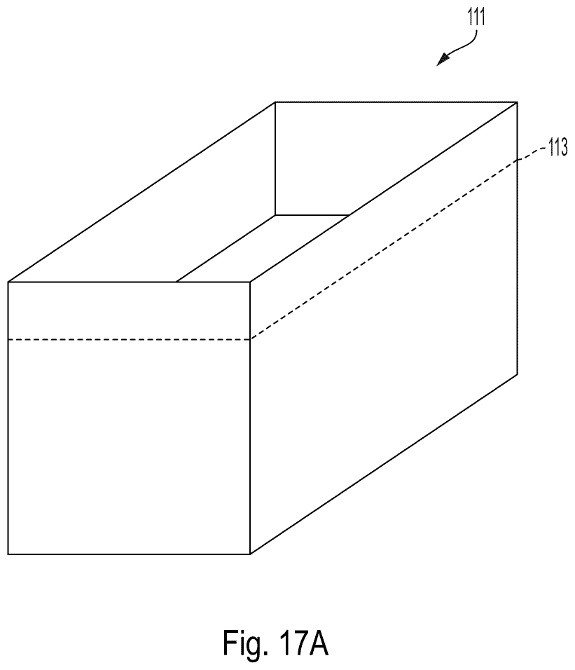

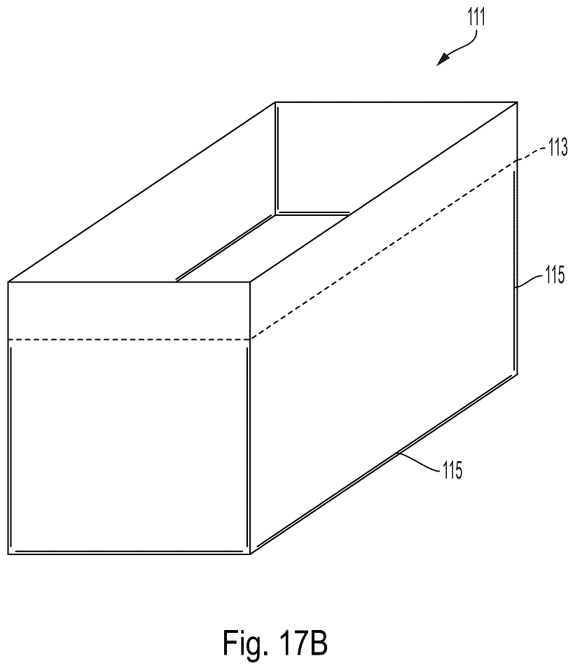

The reusable liner may have a shape conforming to the interior of the cavity to receive the liner. FIGS. 17A and 17B illustrate embodiments of a reusable liner 111. As shown, a reusable liner 11 for use with a block ice machine such as shown in FIG. 1A may have a rectangular shape with 4 side walls and a bottom surface. Corner edges exist at the intersection of each side wall with a neighboring side wall and bottom edges exist at the intersection of each side wall and the bottom surface.

The sidewalls may extend upwardly beyond the cavity such that they may be folded over top edges of the cavity. Flex point 113 is shown where the sidewalls may be folded. It is to be appreciated that the sidewalls may be folded at any suitable point depending on sizing of the cavity and that identification of 113 is done merely for illustrative purposes. Further, in some embodiments, the liner may not be folded over edges of the cavity. The fold over the top of the metal cavity facilitates an improved seal and minimizes water leakage. Depending on the block size, the reusable liner may be used for transport or storage, provides a barrier between packaging and shipping, and provided grip to the block for transport.

FIG. 17B illustrates a reusable liner 111 having reinforcement rods 115, in accordance with one embodiment. Reinforcement rods, such as metal rods, may be integrated into the reusable liner at one or more of the corner edges or bottom edges of the liner 111. For example, reinforcement rods may be provided at one or more of the corner extensions between adjacent sidewalls, at one or more of the corner extensions between adjacent sidewalls and the bottom surface, or both. The reinforcement rods facilitate squaring up of the reusable liner to the cavity.

Hooks or fasteners may be removably or permanently integrated into one or more of the sidewalls, in some embodiments. These may be used for receiving a lifting mechanism and being pulled out of the cavity. For example, magnets may be provided for facilitating clipping in. In some embodiments, the reusable liner may include integrated magnetic elements embedded in the upper edges, configured to align and securely clip into ferromagnetic or magnetized anchoring plates on an ice mold frame or a cavity. This aids in precision placement and reduces liner movement during the freeze cycle. In some embodiments, components in contact with consumable products may conform to applicable health and sanitation standards, including but not limited to NSF/ANSI 2, NSF/ANSI 4, or NSF/ANSI 51, depending on the specific use case. Electrical components used in refrigerated or humid environments may be rated to UL, CSA, or IEC safety standards to ensure compliance in food-grade manufacturing environments. These certifications may help meet local or international regulatory requirements, particularly for commercial food production and export markets.

In some embodiments, pockets may be integrated into one or more of the sidewalls and/or bottom surface to receive thermal paste or similar thermal transfer material to enhance heat transfer.

In some embodiments, a complementary lid may be provided with the reusable silicone liner to trap cold air and improve freezing efficiency. The lid may be sized to extend over the top of the cavity, co-extending at least partially with the silicone liner folded over the top edges of the cavity.

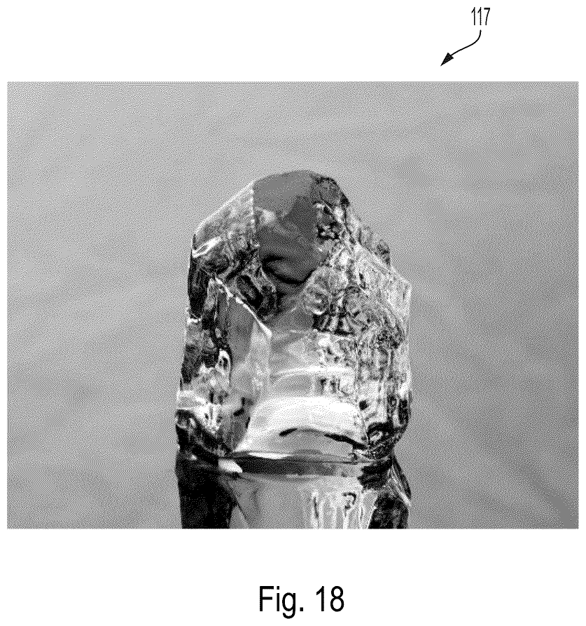

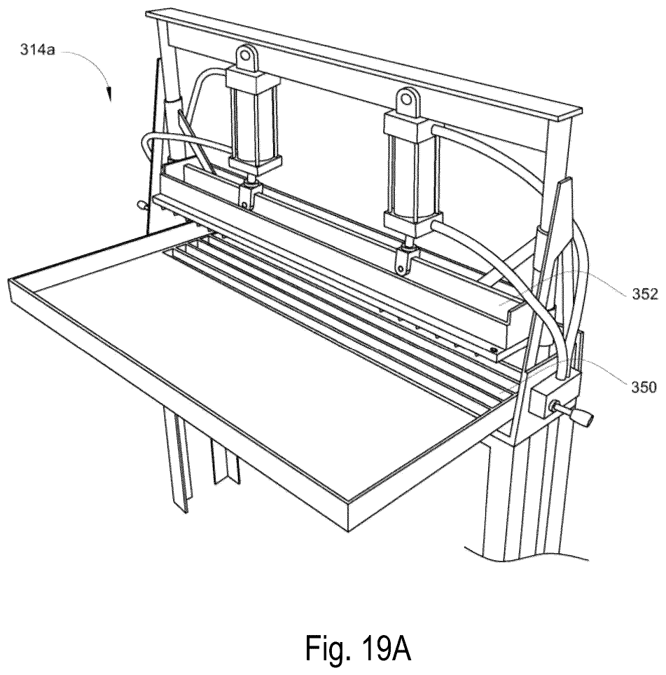

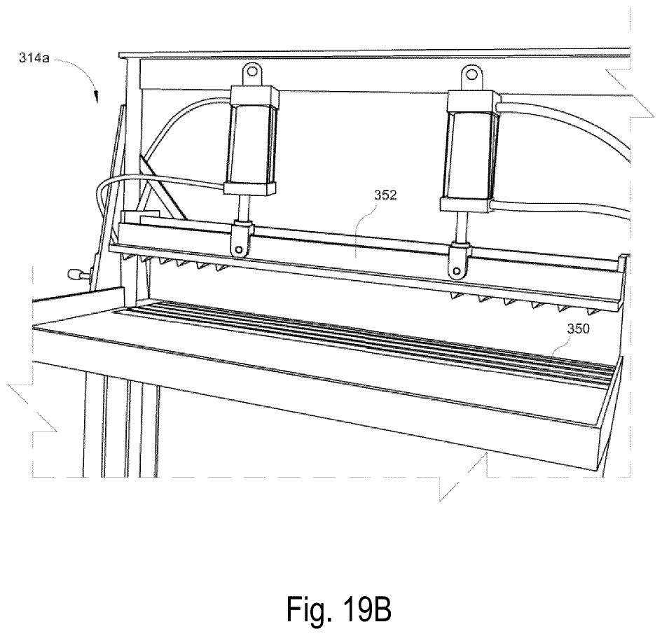

Turning now to other types of small form ice products, in other embodiments, the converting station may operate to convert an ice sheet, or canned ice or block ice product, into shards. In some embodiments, such converting station may comprise a crushing station. An ice shard is an irregularly shaped chunk of ice that is formed by crushing or grinding a larger ice form, such as an ice sheet. In some embodiments, the ice shards may have dimensions of approximately 1-2″ in any given direction (height, width, length). FIG. 18 illustrates an example ice shard 117. Ice shards are generally dense and have surface area along only the outside of the form. As a result, the ice shards typically last 3-4 times longer without fully melting than regular bagged tube ice.

FIGS. 19A and 19B, illustrate a crushing station 314a in accordance with one embodiment. The crushing station includes a substrate with a grid 350 and a mechanical crusher 352 that pushes the ice down through the grid. Alternatively, the crushing substation may comprise pneumatic air pumps and ice picks that are set to turn on and randomly chop the ice. In yet other embodiments, crushing may be via a jaw crusher.

After crushing, the chunks may be directed to a packaging module. This may be done, for example, by pushing the chunks from the stamping and crushing substation to the packaging module. Ice shards may be packaged as bagged ice suitable for use, for example, in a freezer. Typical bagged ice can have air bubbles and is not dense.

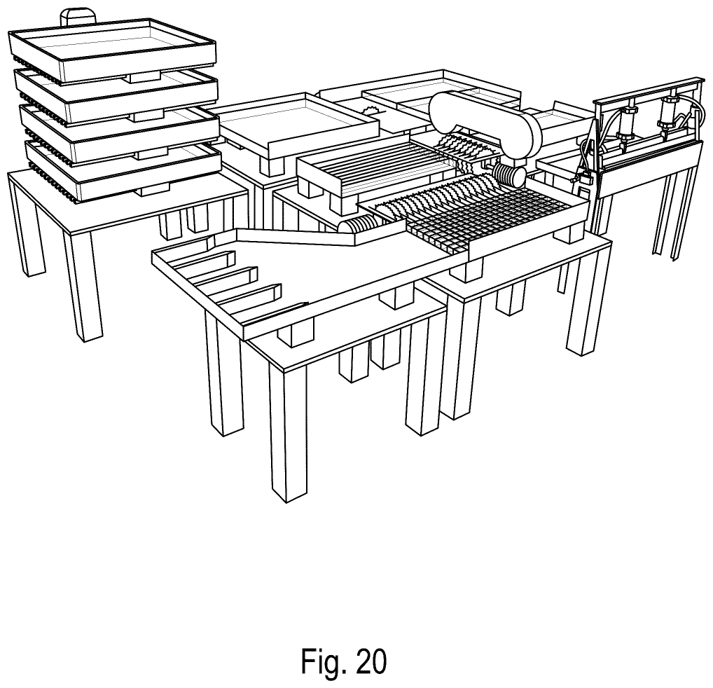

FIG. 20 illustrates an ice forming and cutting system, in accordance with one embodiment. The ice forming and cutting system includes a freeze plate module, a lift module, a slit module, a plane and rod module, a stamp and crack module, and a cube and pack module. In some embodiments, one or more of these modules may be omitted.

The ice forming and cutting system freezes water into clear sheets of ice of varying thickness and converts them into predetermined sized cubes. When a sheet of instructed thickness is called for, it will pass through an adjustable horizontal bandsaw which will rid the sheet of its inconsistently frozen top layer and create a flat and uniform sheet which can be used for further processing. Once this uniform sheet is created, it will pass through a first cutting station, such as gang saw, configured to create rods of ice sized to relation of the sheet thickness called for. These rods will then be transferred through a second cutting station, such as a second gang saw, to convert the strips into cubes. Optionally, a holding freezer may be provided for storing and indexing formed sheets before conversion. In various embodiments, up to 16 molds and accompanying freeze plates may be provided

FIGS. 21A and 21B illustrate a freeze plate module, in accordance with one embodiment. The freeze plate module includes one or more freeze plates (4 shown) with silicone molds and a module frame. A custom user interface for machine control may be provided to control the freeze plate module. The module frame circulates the water while the water is freezes to clear ice. The module may utilize a sensor/switch to automatically move the module frame up as the sheet of ice freezes to ensure none of the modules freeze into the material in process. The sensor/switch may further relay information back to the machine control system informing it when the ice sheet has reached the programmed or desired thickness. Excess water may be removed from the mold utilizing the module frame and the ice sheet may be indexed and/or moved to the next station.

In some embodiments the clear ice sheets may have varying heights. For example, the ice sheets may range from a thickness of 1.5″ to 5″. Because of the inconsistent way ice forms during freezing, the molds may be overfilled with water ˜2″ over the desired ice height to ensure a proper sheet thickness after processing. In order to achieve the proper thicknesses without over filling the molds, volumetric pumps may be used to ensure the machine is only cooling the amount of water needed for the called-for sheet thickness. In order to create clear ice, the freezing has to be directional (bottom to top). Recirculating water pumps may be provided to allow air bubbles to escape as the water begins to freeze. Sensors may be provided to signal when the ice has reached the proper thickness needed for processing. When the ice has achieved this thickness, excess standing water can be pumped out of the mold before the ice is transferred.

Reusable liners offer a reduction in waste compared to single-use plastic liners, supporting sustainability goals. These liners can also reduce operational cost over time and improve reliability in high-volume manufacturing environments. In certain embodiments, the reusable liner includes embedded reinforcement rods along the vertical and bottom corner seams. These rods, which may be metal or rigid polymer, ensure that the liner maintains a square shape during filling and freezing, improving structural integrity and reducing leakage or deformation.

Once the sensors determine this thickness has been reached, the mold may be transferred to a demolding station where the ice is demolded. This may be done, for example, using vacuum cups to lift the ice sheet from the mold and direct it for further processing or place it on a tray that will deliver it to an index slot in the holding freezer. In some embodiments, further processing may only be done after a predetermined number of ice sheets have been frozen.

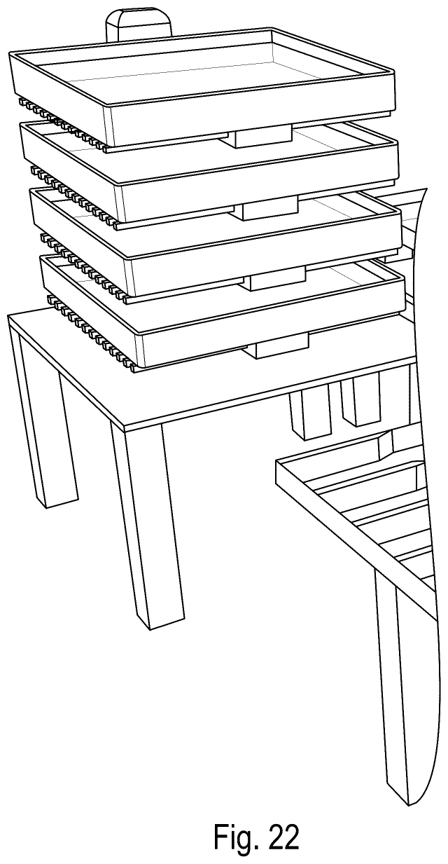

FIG. 22 illustrates a slit module, in accordance with one embodiment. The slit module may convert an ice sheet to a desired dimension for further processing. For example, if the molds form ice sheets of 40″×40″, it may be useful to subdivide each ice sheet into two 20″×40″ sheets to reduce the overall material handling needed in order to fully process the finished material into the final product. This may be done using circular gang saw which splits the original ice sheet into the desired dimensions. Once the original ice sheet has been split, the created ice sheets may be moved to the next station manually or using a pushing device.

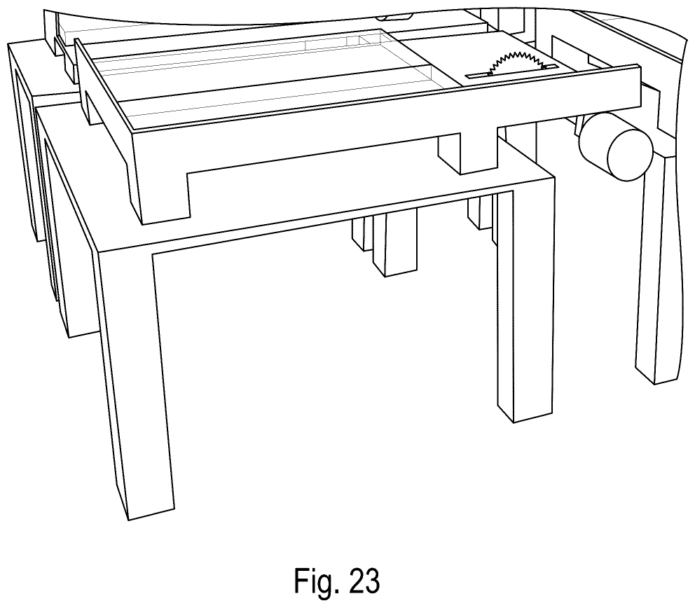

FIG. 23 illustrates a stamp and crack module, in accordance with one embodiment. The stamp and crack module is used in situations where further customization of the formed ice is desired or when it is desired to form shard ice cubes. The stamp and crack module can be used to customize the ice sheet using a stamper or CNC machine or to process the ice sheet to a hydraulic press to crack the ice into a plurality of shards. Formed shards may be directed to fall into a container below the module.

For stamping, the module may use a hydraulic cylinder to push an engraved piece of aluminum down onto the ice to stamp it into the ice with logos, designs, etc. Once this has been complete, the ice is directed for further processing.

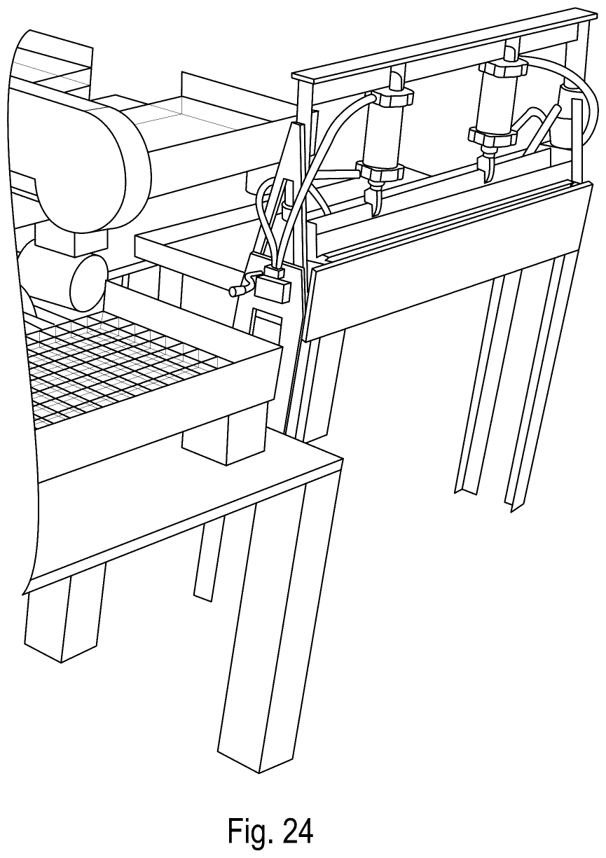

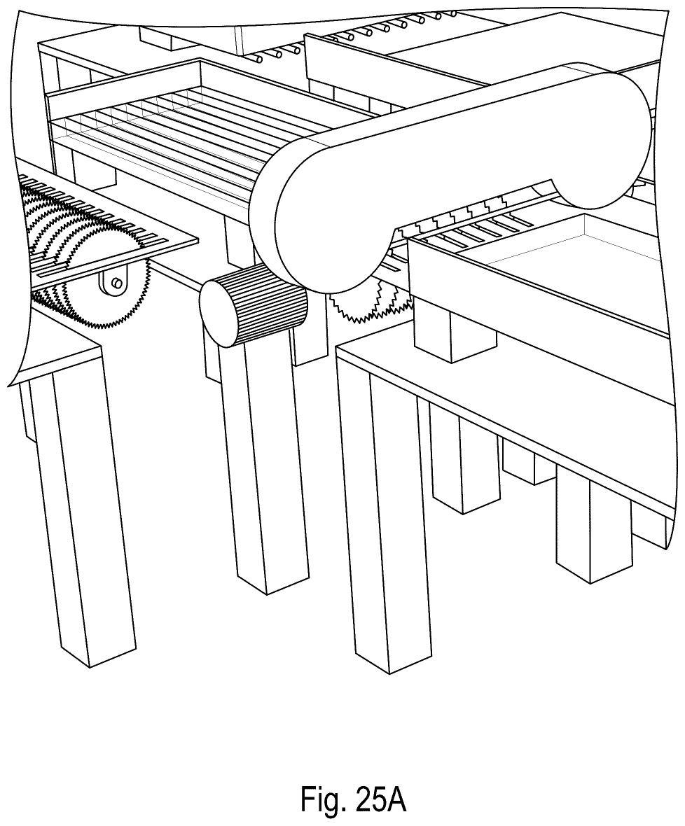

FIG. 24 illustrates a plane and rod module, in accordance with one embodiment. The plane and rod module may comprise a pusher, a bandsaw, and a set of circular gang saws. The pusher pushes the ice sheet through the bandsaw. The bandsaw may be an adjustable height bandsaw for trimming the top of the ice sheet to ensure it is the desired thickness and is level. The trimmed ice sheet is then pushed through the gangsaws, which are used to cut the ice sheet into a plurality of rods. For example, the gangsaws may cut a 2″×20″×40″ gang saw into twenty 2″×2″×40″ rods.

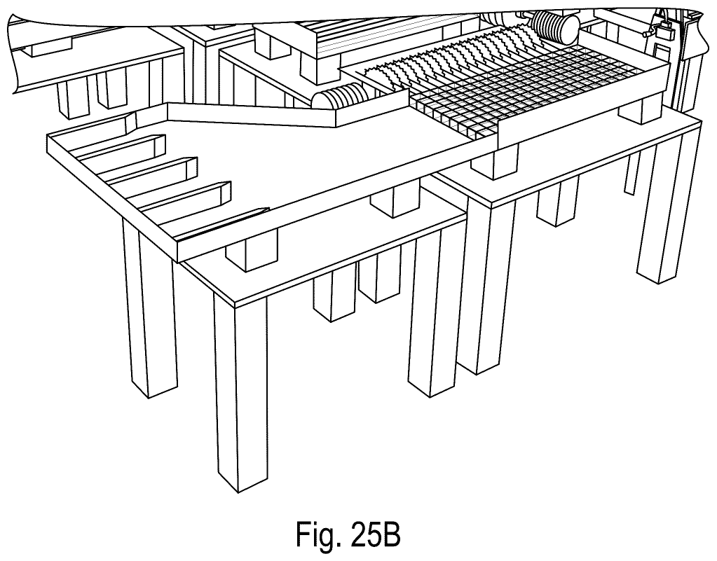

FIGS. 25A and 25B illustrates a cube and pack module, in accordance with one embodiment. The cube and pack module may comprise a pusher and a set of gangsaws. The pusher pushes the ice rods from the plane and rod module to the cube and pack module and through the gangsaws. The gangsaws cut the rods into ice cubes. For example, the gangsaws may cut a 2″×2″×40″ rod into twenty 2″×2″×2″ cubes. Once the cubes have been a pusher may be used to push the cubes to a packing station.

The system for ice cutting, and the components and cutting devices included therein, may comprise a wide range of materials chosen to enhance performance and safety. These may include stainless steel and HDPE, but further may include composite materials or advanced polymers that offer superior thermal insulation, reduced friction, or increased durability. Materials such as graphene-infused plastics or advanced ceramics may be used in high-wear components. Eco-friendly, food grade, recyclable materials might be used to appeal to environmentally conscious markets. In general, any suitable material that provides similar benefits in terms of hygiene, operational efficiency, and compliance with environmental standards may be used. The potential integration with AI-driven manufacturing demand planning may be integrated into the machines eco-sphere.

The system for ice cutting may incorporate a variety of heat management technologies designed to efficiently mitigate heat during operation. These may comprise active cooling systems such as liquid cooling loops, Peltier cooling elements, or phase change materials that activate at predetermined temperatures. The use of advanced thermal conductive enclosures and thermally reactive materials might also be employed to help redirect and dissipate heat away from critical areas. Additionally, the integration of programmable thermal sensors and dynamic cooling regulation systems may be done to allow for real-time adjustments based on operational heat loads, optimizing performance and preventing any compromise to the ice integrity due to melting.

The system is operable in a variety of environments including refrigerated rooms, ambient warehouses, or humid packaging facilities. Optional insulation and drainage features may be incorporated depending on the application and ambient conditions. The system may further include a self-leveling sacrificial pan beneath a cutting surface. This pan may be filled with water and frozen to form a replaceable base slab, allowing blades to pass fully through the ice sheet without damaging equipment. Heating elements or defrost cycles may be triggered to reset the slab between production runs.

Systems and devices may further be incorporated for managing snow melt resulting from heat. This may comprise, for example, a heated capture device (such as a bin) and drain in areas that may have snow melt. In some embodiments, a heated capture device and drain may be provided under one or more motors.

The design of the system for ice cutting allows for significant scalability through the use of modular and interchangeable units that can be configured in various arrangements to suit different production scales. The system may feature adaptive software for automating adjustments to machine settings based on the number of active cutting stations, effectively scaling performance without manual intervention. Scalable networked devices capable of synchronizing operations across multiple machines, facilitated by a cloud-based management system for remote monitoring and configuration, may be used. This technological integration not only demonstrates the advanced capabilities of the system but also enhances its appeal to larger industrial users.

The system for ice cutting is may be customized for specific demands. The customization capabilities are extensive and may include user-configurable interfaces with presets for different types of ice products. Modular attachments that can be easily swapped might allow the machine to shift between producing various ice shapes and sizes, such as flakes, nuggets, cylinders, rectangles, squares, spheres or specialized blocks for sculpting. Additional features can encompass adaptive cutting technologies that automatically adjust blade settings based on real-time assessments of ice block density and temperature. The potential integration with AI-driven design software or production schedules allows users to input custom designs, which are automatically translated into precise cutting instructions, enhancing the system's adaptability and marketability.

In some embodiments, the system may include a programmable controller or HMI (human-machine interface) allowing users to configure batch presets, monitor cutting speeds, and control parameters remotely. Integration with cloud-based monitoring systems may also support predictive maintenance and production scheduling. In advanced embodiments, the system may include a programmable controller with connectivity to external software systems. Applications may include remote monitoring, production scheduling, cloud-based diagnostics, or app-driven alerts when batches are complete. System settings such as cut size, speed, and rotation profiles may be configured through a user interface or mobile application.

The systems and methods disclosed herein may be embodied in a variety of use cases including but not limited to: manual ice sheet subdivision, fully automated food product shaping, or mixed-mode configurations using interchangeable components. Accordingly, the claims should not be limited by the specific examples or embodiments illustrated herein. In various embodiments, the user interface may further be configured to allow operators to:
Select from pre-programmed product profiles (e.g., 2″ cubes, shards, or custom shapes);
Adjust operating parameters based on ambient temperature, humidity, or water supply level;
Receive notifications for maintenance or cleaning cycles; and/or
Pause or reroute processing steps if cube uniformity, blade wear, or environmental thresholds are not met

While the system is described in the context of ice processing, the components, principles, and modular configuration of the system may also be adapted for use with other materials, including but not limited to wood, plastics, food products, and other solid-form raw materials requiring precision cutting or subdivision. In non-ice use cases, interface presets may be customized for material-specific parameters such as wax hardness, plastic flexibility, or wood grain direction, allowing for fine-tuned material processing and quality assurance. Further, each step in the converting process may be performed manually, semi-automatically, or fully automatically. Although the accompanying figures depict a semi-automated implementation, the inventive concepts are not limited to that form.

As used herein, the terms “substantially” or “generally” refer to the complete or nearly complete extent or degree of an action, characteristic, property, state, structure, item, or result. For example, an object that is “substantially” or “generally” enclosed would mean that the object is either completely enclosed or nearly completely enclosed. The exact allowable degree of deviation from absolute completeness may in some cases depend on the specific context. However, generally speaking, the nearness of completion will be so as to have generally the same overall result as if absolute and total completion were obtained. The use of “substantially” or “generally” is equally applicable when used in a negative connotation to refer to the complete or near complete lack of an action, characteristic, property, state, structure, item, or result. For example, an element, combination, embodiment, or composition that is “substantially free of” or “generally free of” an element may still actually contain such element as long as there is generally no significant effect thereof.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

Additionally, as used herein, the phrase “at least one of [X] and [Y],” where X and Y are different components that may be included in an embodiment of the present disclosure, means that the embodiment could include component X without component Y, the embodiment could include the component Y without component X, or the embodiment could include both components X and Y. Similarly, when used with respect to three or more components, such as “at least one of [X], [Y], and [Z],” the phrase means that the embodiment could include any one of the three or more components, any combination or sub-combination of any of the components, or all of the components.

In the foregoing description various embodiments of the present disclosure have been presented for the purpose of illustration and description. They are not intended to be exhaustive or to limit the invention to the precise form disclosed. Obvious modifications or variations are possible in light of the above teachings. The various embodiments were chosen and described to provide the best illustration of the principals of the disclosure and their practical application, and to enable one of ordinary skill in the art to utilize the various embodiments with various modifications as are suited to the particular use contemplated. All such modifications and variations are within the scope of the present disclosure as determined by the appended claims when interpreted in accordance with the breadth they are fairly, legally, and equitably entitled.

What is claimed is:

1. A system for forming small form ice units, the system comprising:
a formation module configured to produce a large form ice structure;
a converting station comprising:
a first cutting station having a first cutting mechanism to cut the ice sheet into a plurality of elongated segments; and
a second cutting station having a second cutting mechanism configured to cut the elongated segments into small form ice units.

2. The system of claim 1, wherein the formation module produces ice sheets having a height of less than six inches, wherein the formation module includes a freeze plate, a freeze frame, and a mold, wherein the mold has a height, a length, and a width, wherein each of the length and the width are more than twice the height, and wherein the mold is supported by the freeze frame.

3. The system of claim 1, wherein each of the first cutting mechanism and the second cutting mechanism comprise a gangsaw unit.

4. The system of claim 3, wherein each gangsaw unit comprises a plurality of mandrels and a plurality of blades on each mandrel, wherein the plurality of blades on each mandrel differ from one another either in size or spacing.

5. The system of claim 4, wherein each gangsaw comprises three mandrels arranged in a triangular configuration and a plurality of blades on each mandrel, wherein the plurality of blades on each mandrel differ from one another either in size or spacing.

6. The system of claim 3, wherein the first cutting station has a first puller for moving the ice sheet to and through the first cutting mechanism and the second cutting station has a second puller for moving the plurality of elongated segments to and through the second cutting mechanism.

7. The system of claim 6, wherein each of the first puller and the second puller have a plurality of fingers having spaces therebetween, wherein the spaces accommodate blades on the first cutting mechanism and the second cutting mechanism respectively.

8. The system of claim 6, wherein at least one of the first puller and the second puller is pivotable between an upper position wherein the ice sheet can be moved under the puller and a deployed position wherein the puller engages the ice sheet.

9. The system of claim 1, further comprising a customization module configured to engrave, stamp, or mill a surface design on the large form ice structure prior to cutting.

10. The system of claim 1, wherein at least one of the first cutting station or the second cutting station includes a sacrificial ice base for receiving the respective first cutting mechanism or second cutting mechanism.

11. The system of claim 1, wherein the converting station further comprises a redirect point between the first cutting station and the second cutting station, wherein the ice sheet travels in a first direction through the first cutting station and then is directed in a second direction at the redirect point for traveling through the second cutting station.

12. The system of claim 1, wherein the large scale ice structure is an ice block having a height of or exceeding six inches, and further comprising a slab station, wherein the ice block is cut into a plurality of ice sheets.

13. The system of claim 1, wherein the formation module includes an ice block maker having a cavity and a reusable liner for use in forming the large form ice structure in the cavity.

14. The system of claim 13, wherein the reusable liner has a thickness between 0.1 mm and 5 mm.

15. A method for forming small form ice units, the method comprising:
forming an ice sheet in a mold, wherein the mold has a height, a length, and a width, wherein each of the length and the width are more than twice the height;
transporting the ice sheet to a first cutting station, the first cutting station having a first cutting mechanism;
cutting the ice sheet in a first direction using the first cutting mechanism to form a plurality of elongated segments; and
cutting the elongated segments in a second direction to form small form ice units.

16. The method of claim 15, wherein the ice sheet has a height approximately 40 inches, a width of approximately 20 inches, and a height between 1.5 and 5 inches, and wherein the small form ice units are 2″×2″×2″ ice cubes.

17. The method of claim 16, further comprising dynamically adjusting blade spacing or cutting speed.

18. The method of claim 15, wherein the first cutting mechanism comprises a gangsaw unit having a plurality of mandrels and a plurality of blades on each mandrel, wherein the plurality of blades on each mandrel differ from one another either in size or spacing.

19. The method of claim 15, wherein cutting the ice sheet in a second cutting direction is done at a second cutting station having a second cutting mechanism.

20. The method of claim 15, wherein cutting the ice sheet in a second cutting direction is done by changing an orientation of either the ice sheet or the first cutting mechanism at the first cutting station.
